(19) United States
(12) Patent Application Publication
(10) Pub. No.: US 2012/0045721 A1
(43) Pub. Date: Feb. 23, 2012

(54) METHOD FOR FORMING A SELF-ALIGNED DOUBLE PATTERN

(75) Inventors: Wallace P. Printz, Austin, TX (US); Steven Scheer, Austin, TX (US)

(73) Assignee: Tokyo Electron Limited, Tokyo (JP)

(21) Appl. No.: 12/858,919

(22) Filed: Aug. 18, 2010

(51) Int. Cl. G03F 7/20

(52) U.S. Cl. 430/312; 430/324

(57) ABSTRACT

The invention can provide a method of processing a substrate using Double-Patterned-Shadow (D-P-S) processing sequences that can include (D-P-S) creation procedures, (D-P-S) evaluation procedures, and (D-P-S) transfer sequences. The (D-P-S) creation procedures can include deposition procedures, activation procedures, de-protecting procedures, sidewall angle (SWA) correction procedure, and Double Patterned (DP) developing procedures.

### CROSS-REFERENCE TO RELATED APPLICATIONS

This application is related to co-pending application Attorney Docket number CT-083, entitled “Technique to Form a Self-Aligned Double Pattern”, filed on even date herewith, the contents of which are herein incorporated by reference in their entirety.

### BACKGROUND OF THE INVENTION

1. Field of the Invention

The present invention relates to substrate processing, and more particularly to improving the substrate processing using Double-Patterned-Shadow (D-P-S) procedures and subsystems.

2. Description of the Related Art

Methods of shrinking line-widths in lithographic processes have historically involved using greater-NA optics, shorter exposure wavelengths, or interfacial media other than air (e.g., water immersion). As the resolution of traditional lithographic processes has approached theoretical limits, manufacturers have started to turn to double-patterning (DP) methods to overcome optical limitations. In DP lithography, the pattern is formed in two passes through the lithography cell. In some instances, the first pattern is etched into the substrate prior to the second pass; while in other instances, the first and second pass through the lithography cell is performed without an intermediate etch. The former method is referred to as Litho-Etch-Litho-Etch double patterning (LELE), and the latter as Litho-Litho-Etch double patterning (LLE). If the material properties of the resist are very similar between the first and second pass, LLE methods may include a “freeze” process after the first patterns are formed in order to inhibit dissolution during the second lithographic pass. The processing steps necessary to form the pattern for the first and second pass are effectively identical in both the LELE and LLE methods.

In contrast to the aforementioned DP methods, the disclosed invention avoids many unnecessary processing steps in forming the second line pattern. Several methods are explained that allow formation of the second pattern solely in the coater-developer track, thus reducing the manufacturing cost of DP patterning. Finally, the disclosed invention potentially allows creation of greater-than-double pattern replication, at pattern densities unachievable with current optical methods.

### SUMMARY OF THE INVENTION

The disclosed invention is designed to form an additional pattern between existing patterns.

Furthermore, the disclosed invention is designed to be self-aligning between the first and second patterns.

Furthermore, the disclosed invention is designed to have a lower cost of manufacturing compared to traditional DP methods.

Furthermore, the disclosed invention is designed to reduce the throughput overhead in the exposure portion of the lithographic cell. A second pattern is formed even though only one pass was necessary through the exposure tool. The present invention provides a method of processing a substrate in real-time using S-D processing procedures and/or S-D evaluation procedures. In some embodiments, one or more controllers in one or more subsystems and/or systems can be used to perform S-D processing procedures and/or S-D evaluation procedures using real-time S-D parameters. In addition, S-D processing procedures and/or S-D measurement procedures may operate using historical data.

Other aspects of the invention will be made apparent from the description that follows and from the drawings appended hereto.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 is a top view of a schematic diagram of a processing system for use in accordance with embodiments of the invention;

FIG. 2 is a front view of the processing system of FIG. 1;

FIG. 3 is a partially cut-away back view of the processing system of FIG. 1, as taken along line 3-3;

FIG. 4 shows an exemplary flow diagram for a Double-Patterned-Shadow (D-P-S) procedure in accordance with embodiments of the invention;

FIGS. 5A-5F illustrate a simplified representation of exemplary steps in a Double-Patterned-Shadow (D-P-S) procedure in accordance with embodiments of the invention;

FIG. 6 shows another exemplary flow diagram for a Double-Patterned-Shadow (D-P-S) procedure in accordance with embodiments of the invention;

FIGS. 7A-7H illustrate another simplified representation of exemplary steps in a Double-Patterned-Shadow (D-P-S) procedure in accordance with embodiments of the invention;

FIG. 8 shows an exemplary block diagram of a Double-Patterned-Shadow (D-P-S) subsystem in accordance with embodiments of the invention;

FIG. 9 shows an exemplary block diagram of another Double-Patterned-Shadow (D-P-S) subsystem in accordance with embodiments of the invention;

FIG. 10 shows exemplary sensitivity data in accordance with embodiments of the invention;

FIG. 11 shows exemplary sidewall angle data after development in accordance with embodiments of the invention;

FIGS. 12A-12E show exemplary Double-Patterned-Shadow (D-P-S) data in accordance with embodiments of the invention; and

FIGS. 13A-13B show exemplary Triple-Patterned-Shadow (T-P-S) data in accordance with embodiments of the invention.

### DETAILED DESCRIPTION

In some embodiments, the Double-Patterned-Shadow (D-P-S) processing sequence can include a number of (D-P-S) procedures. In a first step, a first lithographic procedure can be performed to create a first patterned substrate that includes a first patterned layer in which the pattern pitch can be established at (1:4) ratio. For example, 193 nm illumination is used to create a dense-array pattern of 100 nm lines with 300 nm spaces. In a second step, a “freeze” layer, generally an inorganic thin film, can be applied to the first patterned layer. In addition, the freeze film properties can be tuned to selectively allow acid, but not allow developer solution, to migrate through the film.

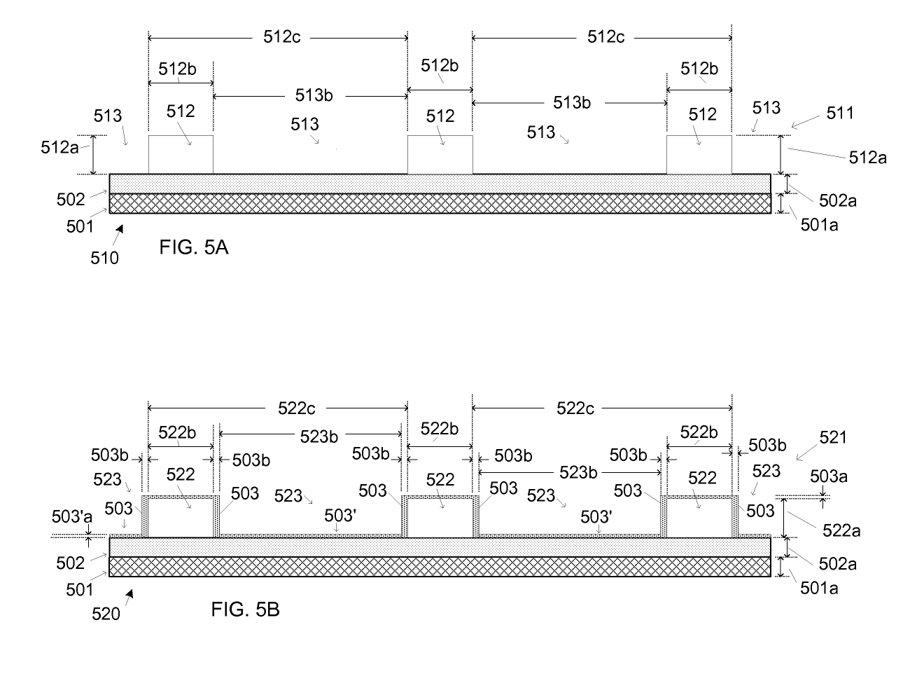

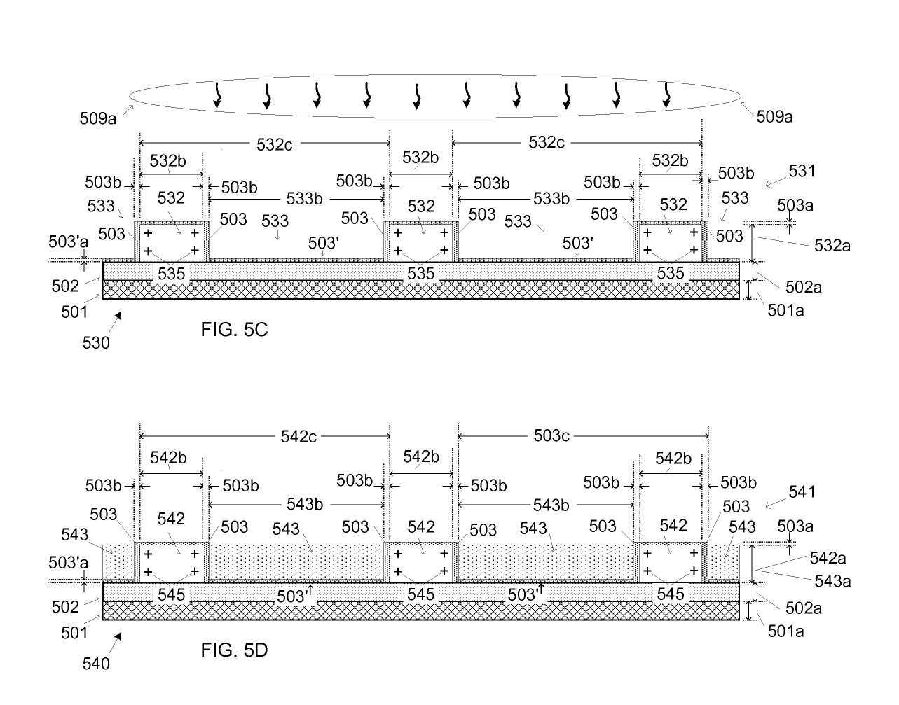

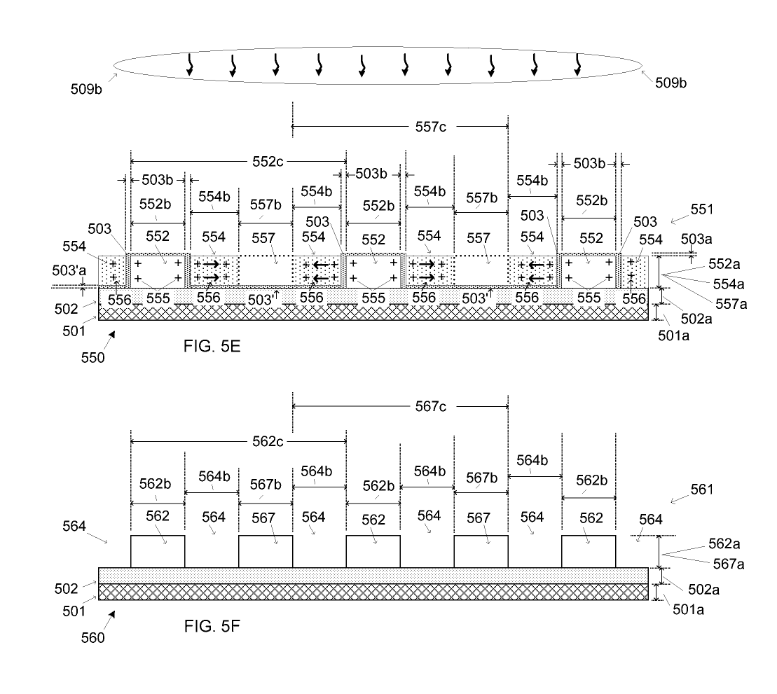

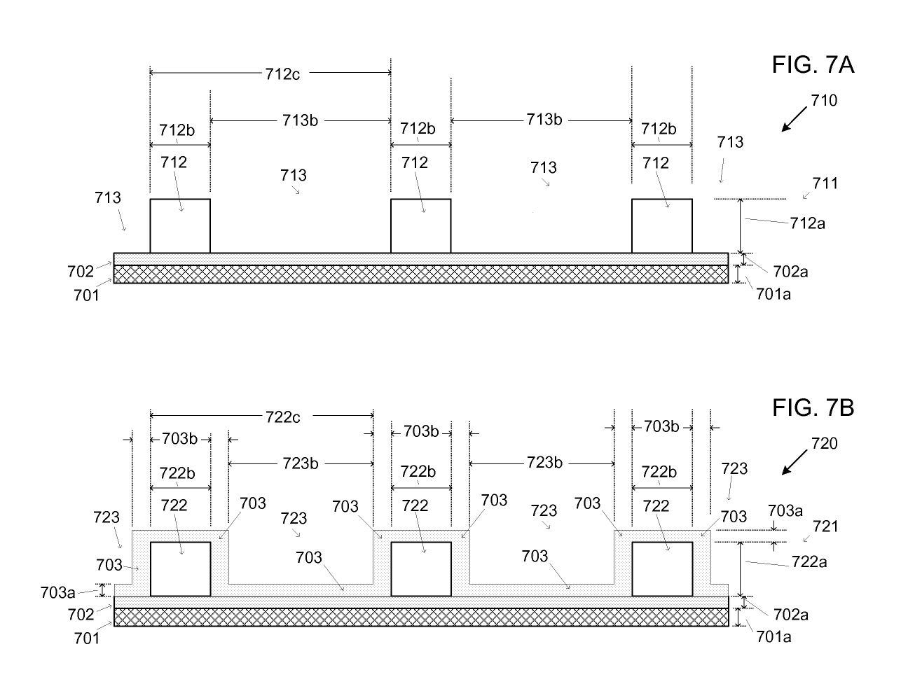

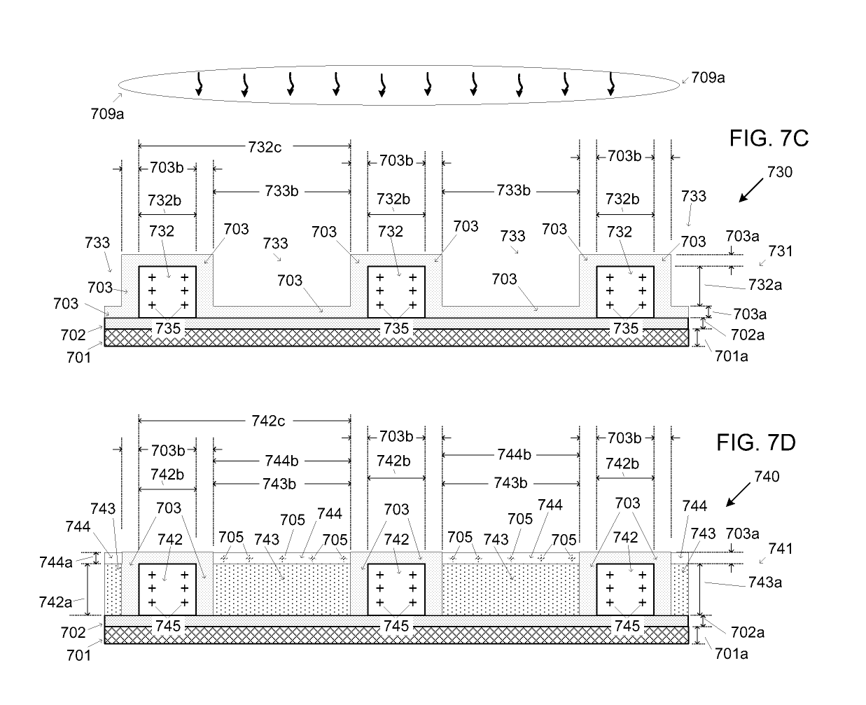

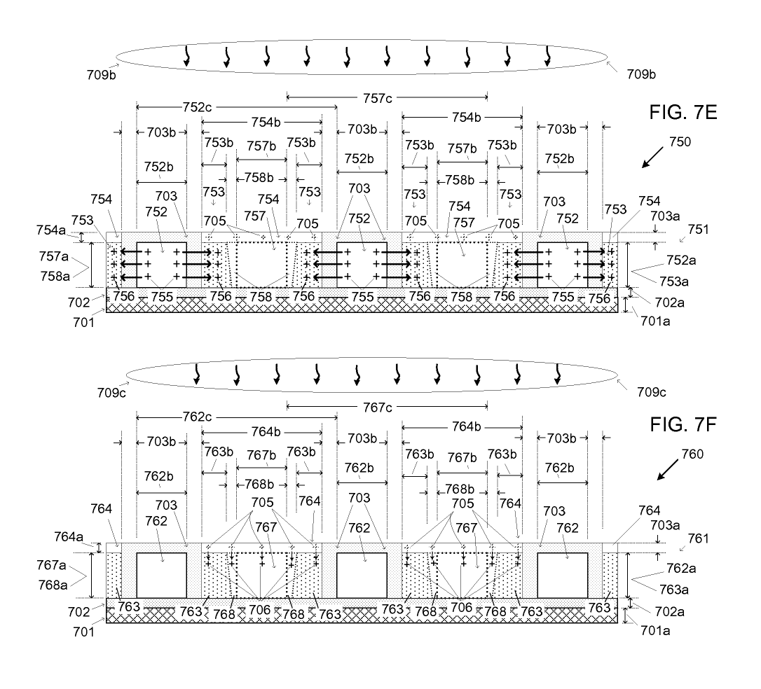

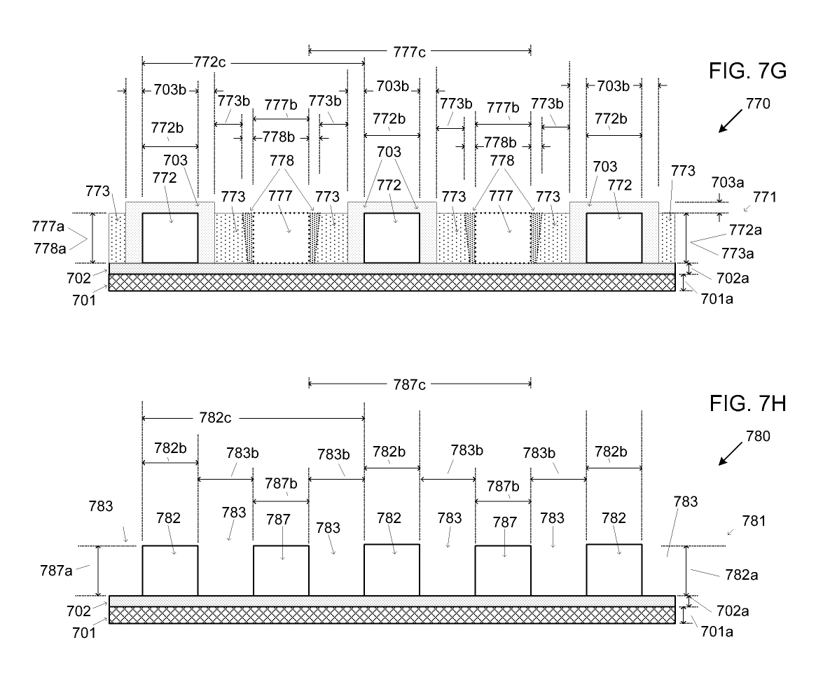

In a third step, the resist features in the first patterned layer pattern can be modified to contain a large concentration of acid, indicated in (FIG. 5 and FIG. 7) by plus symbol (“+”). For example, acid can be generated in the resist features in the first patterned layer using at least one radiation pattern. One method of generating acid is by performing a blanket exposure of the resist to radiation at a wavelength that activates a photoactive acid-generating compound (PAG) present in the resist. This method is achievable because, in the case the first pattern was generated using a positive-tone resist, the remaining pattern after development maintains a high concentration of PAG. In a fourth step, a second resist layer can be deposited over the first layer. In a fifth step, the substrate can be baked to drive acid diffusion from the resist features in the first patterned layer into the second resist in the second resist layer. The timing and the temperature of the bake step are tuned to drive enough acid into the second resist in the second resist layer so that a “self-aligned” second feature having the desired width, and not containing any acid, can be created. Next, the substrate can be processed as usual in the develop chamber. In the case of a positive-tone resist, the acid-rich areas of the second resist in the second resist layer can be developed away and the acid-poor regions can remain after development. When the Double-Patterned-Shadow (D-P-S) processing sequence is completed, the interstitial space between pattern features can be filled with an additional pattern in a triple pattern procedure.

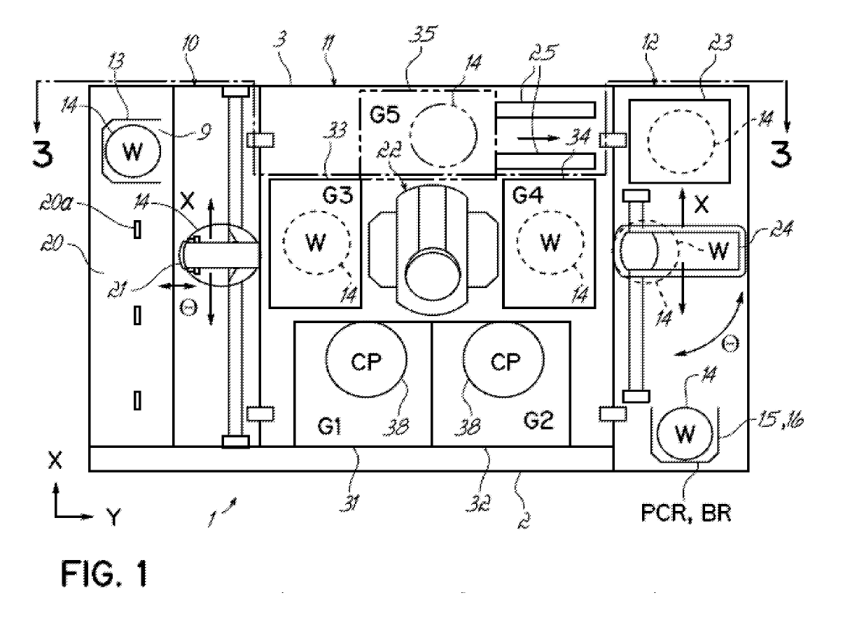

With reference to FIGS. 1-3, a processing system 1 has a load/unload section 10, a process section 11, and an interface section 12. The load/unload section 10 has a cassette table 20 on which cassettes (CR) 13, each storing a plurality of semiconductor substrates (W) 14 (e.g., 25), are loaded and unloaded from the processing system 1. The process section 11 has various single substrate processing units for processing substrates 14 sequentially one by one. These processing units are arranged in predetermined positions of multiple stages, for example, within first (G1), second (G2), third (G3), fourth (G4) and fifth (G5) multiple-stage process unit groups 31, 32, 33, 34, 35. The interface section 12 is interposed between the process section 11 and one or more light exposure systems (not shown), and is configured to transfer resist coated substrates between the process section. The one or more light exposure systems can include a resist patterning system such as a photolithography tool that transfers the image of a circuit or a component from a mask or onto a resist on the substrate surface.

The processing system 1 also includes a CD metrology system for obtaining CD metrology data from test areas on the patterned substrates. The CD metrology system may be located within the processing system 1, for example at one of the multiple-stage process unit groups 31, 32, 33, 34, 35. The CD metrology system can be a light scattering system such as an Optical Digital Profilometry (ODP) system.

The ODP system may include a scatterometer, incorporating beam profile ellipsometry (ellipsometer), and beam profile reflectometry (reflectometer), commercially available from Therma-Wave, Inc. (1250 Reliance Way, Fremont, Calif. 94539) or Nanometrics, Inc. (1550 Buckeye Drive, Milpitas, Calif. 95035). ODP software is available from Timbre Technologies Inc. (2953 Bunker Hill Lane, Santa Clara, Calif. 95054).

When performing optical metrology, such as Scatterometry, a structure on a substrate, such as a semiconductor substrate or flat panel, is illuminated with electromagnetic (EM) radiation, and a diffracted signal received from the structure is utilized to reconstruct the profile of the structure. The structure may include a periodic structure, or a non-periodic structure. Additionally, the structure may include an operating structure on the substrate (i.e., a via, or contact hole, or an interconnect line or trench, or a feature formed in a mask layer associated therewith), or the structure may include a periodic grating or non-periodic grating formed proximate to an operating structure formed on a substrate. For example, the periodic grating can be formed adjacent a transistor formed on the substrate. Alternatively, the periodic grating can be formed in an area of the transistor that does not interfere with the operation of the transistor. The profile of the periodic grating is obtained to determine whether the periodic grating, and by extension the operating structure adjacent the periodic grating, has been fabricated according to specifications.

Still referring to FIGS. 1-3, a plurality of projections 20a are formed on the cassette table 20. A plurality of cassettes 13 are each oriented relative to the process section 11 by these projections 20a. Each of the cassettes 13 mounted on the cassette table 20 has a load/unload opening 9 facing the process section 11.

The load/unload section 10 includes a first sub-arm mechanism 21 that is responsible for loading/unloading the substrate W into/from each cassette 13. The first sub-arm mechanism 21 has a holder portion for holding the substrate 14, a back and forth moving mechanism (not shown) for moving the holder portion back and forth, an X-axis moving mechanism (not shown) for moving the holder portion in an X-axis direction, a Z-axis moving mechanism (not shown) for moving the holder portion in a Z-axis direction, and a θ (theta) rotation mechanism (not shown) for rotating the holder portion around the Z-axis. The first sub-arm mechanism 21 can gain access to an alignment unit (ALIM) 41 and an extension unit (EXT) 42 belonging to a third (G3) process unit group 33, as further described below.

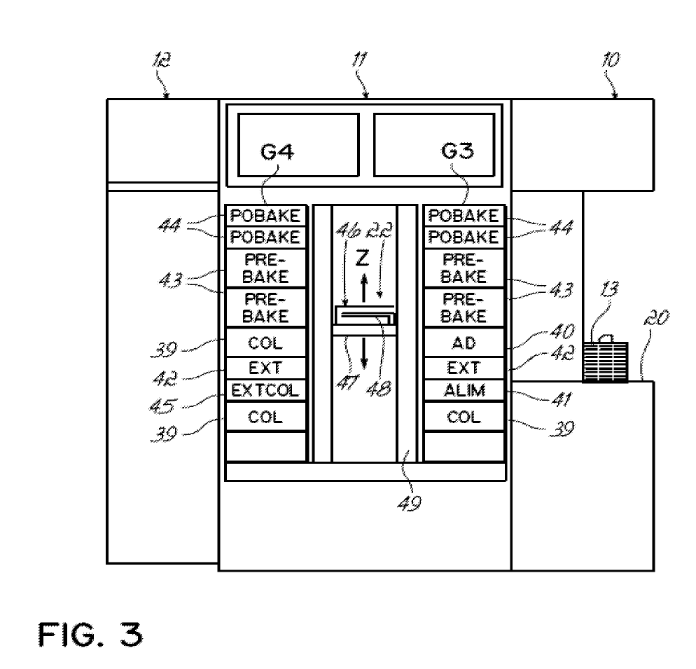

With specific reference to FIG. 3, a main arm mechanism 22 is liftably arranged at the center of the process section 11. The process units G1-G5 are arranged around the main arm mechanism 22. The main arm mechanism 22 is arranged within a cylindrical supporting body 49 and has a liftable substrate transporting system 46. The cylindrical supporting body 49 is connected to a driving shaft of a motor (not shown). The driving shaft may be rotated about the Z-axis in synchronism with the substrate transporting system 46 by an angle of θ. The substrate transporting system 46 has a plurality of holder portions 48 movable in a front and rear direction of a transfer base table 47.

Units belonging to first (G1) and second (G2) process unit groups 31, 32, are arranged at the front portion 2 of the processing system 1. Units belonging to the third (G3) process unit group 33 are arranged next to the load/unload section 10. Units belonging to a fourth (G4) process unit group 34 are arranged next to the interface section 12. Units belonging to a fifth (G5) process unit group 35 are arranged in a back portion 3 of the processing system 1.

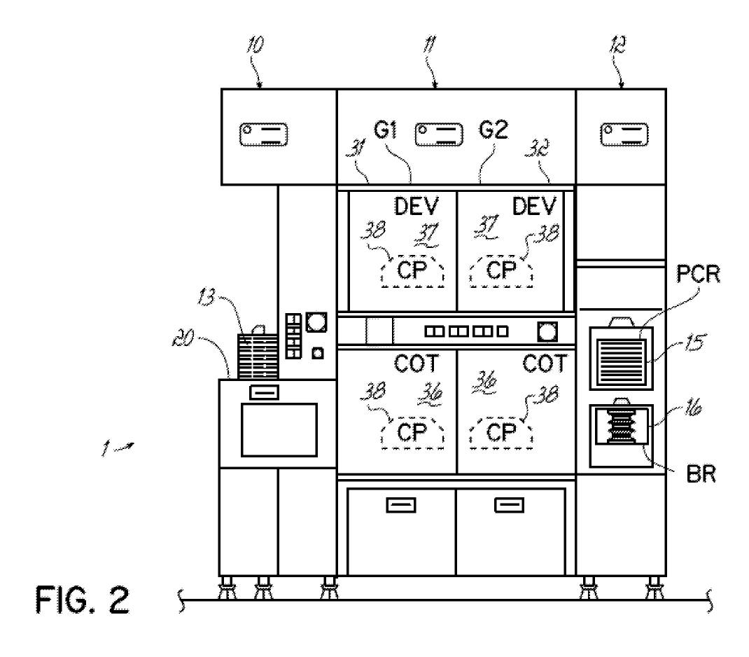

With reference to FIG. 2, the first (G1) process unit group 31 has two spinner-type process units for applying a predetermined treatment to the substrate 14 mounted on a spin chuck (not shown) within the cup (CP) 38. In the first (G1) process unit group 31, for example, a resist coating unit (COT) 36 and a developing unit (DEV) 37 are stacked in two stages sequentially from the bottom. In the second (G2) process unit group 32, two spinner type process units such as a resist coating unit (COT) 36 and a developing unit (DEV) 37, are stacked in two stages sequentially from the bottom. In an exemplary embodiment, the resist coating unit (COT) 36 is set at a lower stage than the developing unit (DEV) 37 because a discharge line (not shown) for the resist waste solution is desired to be shorter than a developing waste solution for the reason that the resist waste solution is more difficult to discharge than the developing waste solution. However, if necessary, the resist coating unit (COT) 36 may be arranged at an upper stage relative to the developing unit (DEV) 37.

With reference to FIG. 3, the third (G3) process unit group 33 has a cooling unit (COL) 39, an alignment unit (ALIM) 41, an adhesion unit (AD) 40, an extension unit (EXT) 42, two prebaking units (PREBAKE) 43, and two postbaking units (POBAKE) 44, which are stacked sequentially from the bottom.

Similarly, the fourth (G4) process unit group 34 has a cooling unit (COL) 39, an extension-cooling unit (EXTCOL) 45, an extension unit (EXT) 42, another cooling unit (COL) 39, two prebaking units (PREBAKE) 43 and two postbaking units (POBAKE) 44 stacked sequentially from the bottom. Although, only two prebaking units 43 and only two postbaking units 44 are shown, G3 and G4 may contain any number of prebaking units 43 and postbaking units 44. Furthermore, any or all of the prebaking units 43 and postbaking units 44 may be configured to perform PEB, post application bake (PAB), and post developing bake (PDB) processes.

In an exemplary embodiment, the cooling unit (COL) 39 and the extension cooling unit (EXTCOL) 45, to be operated at low processing temperatures, are arranged at lower stages, and the prebaking unit (PREBAKE) 43, the postbaking unit (POBAKE) 44 and the adhesion unit (AD) 40, to be operated at high temperatures, are arranged at the upper stages. With this arrangement, thermal interference between units may be reduced. Alternatively, these units may have different arrangements.

At the front side of the interface section 12, a movable pick-up cassette (PCR) 15 and a non-movable buffer cassette (BR) 16 are arranged in two stages. At the backside of the interface section 12, a peripheral light exposure system 23 is arranged. The peripheral light exposure system 23 can contain a lithography tool. Alternately, the lithography tool and the ODP system may be remote to and cooperatively coupled to the processing system 1. At the center portion of the interface section 12, a second sub-arm mechanism 24 is provided, which is movable independently in the X and Z directions, and which is capable of gaining access to both cassettes (PCR) 15 and (BR) 16 and the peripheral light exposure system 23. In addition, the second sub-arm mechanism 24 is rotatable around the Z-axis by an angle of θ and is designed to be able to gain access not only to the extension unit (EXT) 42 located in the fourth (G4) process unit group 34 but also to a substrate transfer table (not shown) near a remote light exposure system (not shown).

In the processing system 1, the fifth (G5) process unit group 35 may be arranged at the back portion 3 of the backside of the main arm mechanism 22. The fifth (G5) process unit group 35 may be slidably shifted in the Y-axis direction along a guide rail 25. Since the fifth (G5) process unit group 35 may be shifted as mentioned, maintenance operation may be applied to the main arm mechanism 22 easily from the backside.

The prebaking unit (PREBAKE) 43, the postbaking unit (POBAKE) 44, and the adhesion unit (AD) 40 each comprise a heat treatment system in which substrates 14 are heated to temperatures above room temperature.

The present invention provides apparatus and methods for processing substrates having a large number of semiconductor devices thereon using Double-Patterned-Shadow (D-P-S) procedures, sequences, and/or processing units. In various embodiments, apparatus and methods are provided for performing internal and/or external transfer sequences, for performing internal and/or external processing sequences, and for performing internal and/or external measurement procedures when creating, verifying, using, and/or updating a Double-Patterned-Shadow (D-P-S) evaluation library. One or more creation and/or evaluation sites can be provided at various locations on a (D-P-S) substrate. Sites can be process-related, and one or more of the sites can be used in (D-P-S) evaluation and/or verification procedures. (D-P-S) evaluation and/or verification procedures can be used to evaluate and/or verify (D-P-S) transfer sequences, (D-P-S) substrates, (D-P-S) procedures, (D-P-S) evaluation libraries, (D-P-S) processing sequences, or specific sites used in a (D-P-S) processing step, or any combination thereof.

The (D-P-S) substrates and the (D-P-S) procedures can have (D-P-S) data associated with them, and the (D-P-S) data can include real-time and historical data. The (D-P-S) data can include confidence data and/or risk data for the substrate and/or procedure. The (D-P-S) substrates and the (D-P-S) procedures can have location data and/or site data associated with them, and this data can include the number of required locations and/or sites, the number of visited locations and/or sites, confidence data and/or risk data for one or more of the locations and/or sites, location and/or site ranking data, transferring sequence data, or process-related data, or evaluation/verification-related data, or any combination thereof. The (D-P-S) substrate/substrate data can include one or more (D-P-S) processing sequence variables that can be used to establish the processing sequence procedures. (D-P-S) processing sequences can be changed in real-time to optimize throughput, to maximize the use of processing elements, to maximize the use of evaluation elements, to rework faulty (D-P-S) substrates as soon as possible.

The processing system 1 can be coupled to a manufacturing execution system (MES) (not shown) and the processing system 1 can exchange information with the MES (not shown). In addition, one or more processing systems 1 can be coupled to each other and to other subsystem using the intranet, an internet, wired, and/or wireless connections. The processing system 1 can perform a portion of or all of the processing steps of the invention in response to the computers/processors in the processing system 1 executing one or more sequences of one or more instructions contained in a memory and/or received in a message. Such instructions may be received from another computer, a computer readable medium, or a network connection.

Stored on any one or on any combination of computer readable media, the present invention includes software for controlling the processing system 1, for driving a device or devices for implementing the invention, and for enabling the processing system 1 to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The term “computer readable medium” as used herein refers to any medium that participates in providing instructions to the processor for execution. A computer readable medium may take many forms, including but not limited to, non-volatile media, volatile media, and transmission media.

In some embodiments, an integrated system can be configured using system components from Tokyo Electron Limited (TEL). In other embodiments, external subsystems and/or tools may be included. The integrated system can include one or more etch tools, deposition tools, ALD tools, measurement tools, ionizations tools, polishing tools, coating tools, developing tools, cleaning tools, exposure tools, and thermal treatment tools. In addition, measurement tools can be provided that can include a CD-Scanning Electron Microscopy (CDSEM) tool, a Transmission Electron Microscopy (TEM) tool, a focused ion beam (FIB) tool, an ODP tool, an Atomic Force Microscope (AFM) tool, or another metrology tool. The subsystems and/or processing elements can have different interface requirements, and the controllers can be configured to satisfy these different interface requirements.

The processing system 1 can perform Advanced Process Control (APC) applications, Fault Detection and Classification (FDC), and/or Run-to-Run (R2R) applications. In some embodiments, the processing system 1 can perform (D-P-S) process optimization procedures, (D-P-S) model optimization procedures, or can perform (D-P-S) library optimization procedures, or any combination thereof. The (D-P-S) optimization procedures can use substrate data, models, recipes, and profile data to update and/or optimize a (D-P-S) procedure. For example, the (D-P-S) optimization procedures can be operating in real-time. By using real-time (D-P-S) optimization, more accurate process results can be achieved. In smaller geometry technologies below the 65 nm node, results that are more accurate are required.

As stated above, the processing system 1 can include an integrated Optical Digital Profilometry (iODP) system (not shown). Alternatively, other metrology systems may be used. An iODP tool is available from Timbre Technologies Inc. (a TEL company). For example, ODP techniques can be used to obtain critical dimension (CD) information, structure profile information, or via profile information, and the wavelength ranges for an iODP system can range from less than approximately 200 nm to greater than approximately 700 nm. An exemplary iODP system can include an ODP Profiler Library, a Profiler Application Server (PAS), and ODP Profiler Software. The ODP Profiler Library can comprise an application specific database of optical spectra and its corresponding semiconductor profiles, CDs, and film thicknesses. The PAS can comprise at least one computer that connects with optical hardware and computer network. The PAS handles the data communication, ODP library operation, measurement process, results generation, results analysis, and results output. The ODP Profiler Software includes the software installed on PAS to manage measurement recipe, ODP Profiler library, ODP Profiler data, ODP Profiler results search/match, ODP Profiler results calculation/analysis, data communication, and PAS interface to various metrology tools and computer network.

An alternative procedure for generating (D-P-S) library data can include using a machine learning system (MLS). Prior to generating the library of simulated-diffraction signals, the MLS is trained using known input and output data. In one exemplary embodiment, simulated diffraction signals can be generated using a machine learning system (MLS) employing a machine learning algorithm, such as back-propagation, radial basis function, support vector, kernel regression, and the like.

The processing system 1 can be coupled to an exposure subsystem (not shown), and the exposure subsystem can perform exposure procedures, thermal procedures, drying procedures, measurement procedures, inspection procedures, alignment procedures, and/or storage procedures on one or more (D-P-S) substrates. In addition, the exposure subsystem can be used to perform wet and/or dry exposure procedures on one or more (D-P-S) substrates. In other processing sequences, the exposure subsystem can be used to perform extreme ultraviolet (EUV) exposure procedures on one or more (D-P-S) substrates.

The processing system 1 can be coupled to an etching subsystem (not shown), and the etching subsystem can perform etching procedures, chemical oxide removal (COR) procedure, ashing procedures, inspection procedures, rework procedures, measurement procedures, alignment procedures, and/or storage procedures on one or more (D-P-S) substrates. For example, the etching subsystem can be used to etch the (D-P-S) substrates that have been processed correctly, and the etching subsystem can be used to perform rework procedures as required.

The processing system 1 can be coupled to a deposition subsystem (not shown), and the deposition subsystem can perform physical vapor deposition (PVD) procedures, chemical vapor deposition (CVD) procedures, ionized physical vapor deposition (iPVD) procedures, atomic layer deposition (ALD) procedures, plasma enhanced atomic layer deposition (PEALD) procedures, and/or plasma enhanced chemical vapor deposition (PECVD) procedures.

The processing system 1 can be coupled to an evaluation subsystem (not shown), and the evaluation subsystem can perform evaluation procedures, inspection procedures, temperature control procedures, measurement procedures, alignment procedures, verification procedures, and/or storage procedures on (D-P-S) substrates. For example, the evaluation subsystem can be used to perform optical metrology procedures that can be used to measure features and/or structures on the substrate, and the evaluation subsystem can be used to perform optical inspections of the substrate surface. In addition, the evaluation subsystem can be used to determine substrate curvature or to measure and/or inspect one or more surfaces of the substrates.

The processing system 1 can send and/or receive one or more of the formatted messages, and one or more of the controllers in the processing system 1 can process messages and extract new data. When new data is available, a controller can either use the new data to update a recipe, profile, and/or model currently being used for the substrate lot or can use the new data to update a recipe, profile, and/or model for the next substrate lot. When the controller uses the new data to update recipe data, profile data, and/or modeling data for the substrate lot currently being processed, the controller can determine if a recipe, a profile, and/or a model can be updated before the current substrate is processed. The current substrate can be processed using the updated recipe, profile, and/or model when the recipe, profile, and/or model can be updated before the current substrate is processed. The current substrate can be processed using a non-updated recipe, profile, and/or model when the data cannot be updated before the current substrate is processed. For example, when new (D-P-S) procedures, recipes, profiles, and/or models are available, each controller may determine when to use the new (D-P-S) procedures, recipes, profiles, and/or models.

One or more of the controllers in the processing system 1 can provide (D-P-S) damage-assessment data that can include data for damaged layers, features, and/or structures for different sites, substrates, and/or lots. One or more of the controllers in the processing system 1 can use the damage-assessment data to update, and/or optimize processing recipe data, process profile data, and/or modeling data. For example, a controller can use the damage-assessment data to update, and/or optimize a developing chemistry and/or developing time.

During (D-P-S) processing, monitor and/or verification substrates can be run periodically.

The (D-P-S) data can include measured and/or simulated signals associated with (D-P-S) patterned structures, and the (D-P-S) signals can be stored using operational state data, and substrate, lot, recipe, site, or substrate location data. Measurement data can include variables associated with patterned structure profile, metrology device type and associated variables, and ranges used for the variables floated in the modeling and values of variables that were fixed in the modeling. The library profile data, the (D-P-S) data may include fixed and/or variable profile parameters (such as CD, sidewall angle, n and k parameters), and/or metrology device parameters (such as wavelengths, angle of incidence, and/or azimuth angle). In some embodiments, context/identification information such as site ID, substrate ID, slot ID, lot ID, recipe, state, and patterned structure ID can be used as a means for organizing and indexing (D-P-S) data.

In some example, the (D-P-S) library data can include verified data associated with products, devices, substrates, procedures, lots, recipes, sites, locations, and patterned (D-P-S) structures. The (D-P-S) data may include underlying film data and the underlying film data may be used by the (D-P-S) procedures to make real-time updates and/or corrections. During processing, some measurement sites can be non-measurable due to interference from underlying layers and or structures, and (D-P-S) interference-based maps can be created and used to determine site locations that can be used for the measurements. In addition, (D-P-S) interference profiles and/or models can be created can be used to overcome these problems.

Intervention and/or judgment rules can be defined in a (D-P-S) model and/or (D-P-S) procedure. Intervention and/or judgment rules can be assigned to execute whenever a matching context is encountered. The intervention and/or judgment rules can be for various procedures and can be maintained in the database, and the intervention and/or judgment rules can be used to determine how to manage the data when a process can be changed, paused, and/or stopped.

In general, rules allow (D-P-S) procedures to change based on the dynamic state of the processing system 1 and/or the processing state of a product. Some setup and/or configuration information can be determined by processing units in the processing system 1 when they are initially configured. In addition, rules can be used to establish a control hierarchy for (D-P-S) procedures. Rules can be used to determine when a process can be paused and/or stopped, and what can be done when a process is paused and/or stopped. In addition, processing rules can be used to determine what corrective actions are to be performed. Processing sequence rules and transfer sequence rules can also be used to determine what substrates are to be processes and/or transferred.

One or more of the controllers in the processing system 1 can be configured for establishing a first number of (D-P-S) substrates to be processed using a first unverified (D-P-S) procedure, for establishing a number of required verification sites for each (D-P-S) substrate using the substrate data and the first unverified (D-P-S) procedure, for determining operational state data for the one or more of the processing units in the processing system 1, for determining loading data for the one or more of the processing units in the processing system 1, for establishing a first transfer sequence for a first (D-P-S) substrate in the first number of (D-P-S) substrates using the substrate data, the operational state data, loading data, or the number of required verification sites, or any combination thereof, and for delaying the first (D-P-S) substrate for a first period of time when the first processing unit is not available.

When a (D-P-S) evaluation procedure is performed, a first site can be used, first evaluation data can be obtained from the first site on the first (D-P-S) substrate and evaluation decisions can be made using the evaluation data from the first site and/or other sites. One or more of the controllers in the processing system 1 can be configured for selecting the first site from the number of required sites on the first processed (D-P-S) substrate. For example, the first site can have a first unverified (D-P-S) feature associated therewith that was created using the first unverified (D-P-S) procedure.

When the first evaluation data includes unverified data, a verification procedure can be performed. The unverified data from the first site can be compared to reference data and/or other verified data, and difference data can be calculated using the unverified data and the reference data. The difference data can be compared with accuracy limits, confidence limits, and/or risk limits to establish confidence data and/or risk data to associate with the evaluation data when determining if the evaluation data is verified or unverified data.

When the evaluation data includes unverified data from a number of sites, one or more verification procedures can be performed. The unverified data from the first number of sites can be compared to reference data and/or other verified data, and difference data can be calculated for the first number of sites using the unverified data and the reference data. The difference data can be compared with accuracy limits, confidence limits, and/or risk limits to establish confidence data and/or risk data to associate with the evaluation data for the first number of sites when determining if the evaluation data is verified or unverified data.

In some embodiments, the (D-P-S) evaluation data can include intensity data, transmission data, absorption data, reflectance data, diffraction data, optical properties data, or image data, or any combination thereof. In addition, the (D-P-S) library data can include historical data, verified data, optical metrology data, imaging data, particle data, CD-scanning electron microscope (CD-SEM) data, transmission electron microscope (TEM) data, and/or focused ion beam (FIB) data. The threshold limit can be determined using (D-P-S) data, goodness of fit data, CD data, accuracy data, wavelength data, sidewall angle data, particle data, process data, historical data, or a combination thereof.

In addition, the (D-P-S) operational state data can be dependent on the number of required sites, the number of visited (evaluated/completed) sites, or the number of remaining sites, or any combination thereof. The (D-P-S) operational state data can be dependent on the number of required procedures, the number of completed procedures, or the number of remaining procedures, or any combination thereof. In some cases, the number of evaluations actually performed can be less than the original number when excellent results are obtained at the sites already measured. One or more of the controllers in the processing system 1 can be configured for receiving (D-P-S) operational state data and/or (D-P-S) processing data for the first set of (D-P-S) evaluation substrates.

In some examples, when a first delaying action is performed, one or more of the controllers in the processing system 1 can be configured for determining a first number of delayed (D-P-S) substrates using a difference between the first number of (D-P-S) process substrates and the first number of available processing units in the processing system 1, and one or more of the processing units in the processing system 1 can be configured for storing and/or delaying the first number of delayed substrates for a first period of time.

When corrective actions are required, they can include stopping the processing, pausing the processing, re-evaluating one or more of the (D-P-S) evaluation substrates, re-measuring one or more of the (D-P-S) evaluation substrates, re-inspecting one or more of the (D-P-S) evaluation substrates, re-working one or more of the (D-P-S) evaluation substrates, storing one or more of the (D-P-S) evaluation substrates, cleaning one or more of the (D-P-S) evaluation substrates, delaying one or more of the (D-P-S) evaluation substrates, or stripping one or more of the (D-P-S) evaluation substrates, or any combination thereof.

Sites in (D-P-S) procedures can be associated with a gate structure in a transistor, a drain structure in a transistor, a source structure in a transistor, a capacitor structure, a via structure, a trench structure, a two-dimensional memory structure, a three-dimensional memory structure, a sidewall angle, a bottom critical dimension (CD), a top CD, a middle CD, an array, a periodic structure, an alignment feature, a doping feature, a strain feature, a damaged-structure, or a reference structure, or any combination thereof.

In some cases, the operational state data can include the number of required evaluation-related sites, the number of visited evaluation-related sites, or the number of remaining evaluation-related sites or any combination thereof. A (D-P-S) evaluation procedure can be determined for “to-be-evaluated” sites, substrates, procedures, and/or libraries, and the (D-P-S) evaluation procedure can include one or more verification, evaluation, measurement, inspection, and/or test procedures. In addition, a (D-P-S) evaluation procedure can be determined for “to-be-verified” sites, substrates, procedures, and/or libraries.

In other cases, the operational state data can include the number of required verification-related sites, the number of visited verification-related sites, or the number of remaining verification-related sites or any combination thereof. A (D-P-S) verification procedure can be determined for “to-be-verified” sites, substrates, procedures, and/or libraries, and the (D-P-S) verification procedure can include one or more verification, evaluation, measurement, inspection, and/or test procedures.

Operational state data can be determined for one or more of the processing units in the processing system 1, and the operational state data can be used to determine the one or more available processing units. For example, the operational state data for the processing units can include availability data, matching data for the processing units, expected processing times for some process steps and/or sites, confidence data and/or risk data for the processing units, confidence data, and/or risk data for one or more process-related sites. In some example, real-time operational states can be established for one or more of the processing units in the processing system 1. A first number of (D-P-S) processing substrates can be transferred to a first number of the processing units when the first number of first processing units is available. Other (D-P-S) substrates can be delayed for a first amount of time when processing units are not available. Operational states can change as substrates are transferred into and out of the processing units. Real-time transfer sequences can be established and used to transfer substrates into and out of the processing units in the processing system 1, and updated operational states can be obtained by querying, in real-time, one or more processing units, and/or one or more controllers in the processing system 1. Updated loading data can be obtained by querying in real-time one or more of the loadlocks in the processing system 1.

Delayed substrates can be processed and/or transferred using “delayed” processing sequences and/or “delayed” transfer sequences that can include delayed (D-P-S) procedures and provide delayed data. For example, when a “newly-available” processing unit is identified, a delayed (D-P-S) evaluation substrate can be transferred to the “newly-available” (D-P-S) processing unit in the processing system 1 using a “delayed” transfer sequence.

In some embodiments, the unverified data can include evaluation data for a gate structure in a transistor, a drain structure in a transistor, a source structure in a transistor, a capacitor structure, a via structure, a trench structure, a two-dimensional memory structure, a three-dimensional memory structure, a sidewall angle, a critical dimension (CD), an array, a periodic structure, an alignment feature, a doping feature, a strain feature, a damaged-structure, or a reference structure, or any combination thereof. In other embodiments, the unverified data can include evaluation data, measurement data, inspection data, alignment data, verification data, process data, substrate data, library data, historical data, real-time data, optical data, layer data, thermal data, or time data, or any combination thereof. Alternatively, other data may be used.

In some embodiments, the verified data can include verified, predicted, simulated, and/or library data for a gate structure in a transistor, a drain structure in a transistor, a source structure in a transistor, a capacitor structure, a via structure, a trench structure, a two-dimensional memory structure, a three-dimensional memory structure, a sidewall angle, a critical dimension (CD), an array, a periodic structure, an alignment feature, a doping feature, a strain feature, a damaged-structure, or a reference structure, or any combination thereof. In other embodiments, the verified data can include evaluation data, measurement data, inspection data, alignment data, verification data, process data, substrate data, library data, historical data, real-time data, optical data, layer data, thermal data, or time data, or any combination thereof. Alternatively, other data may be used.

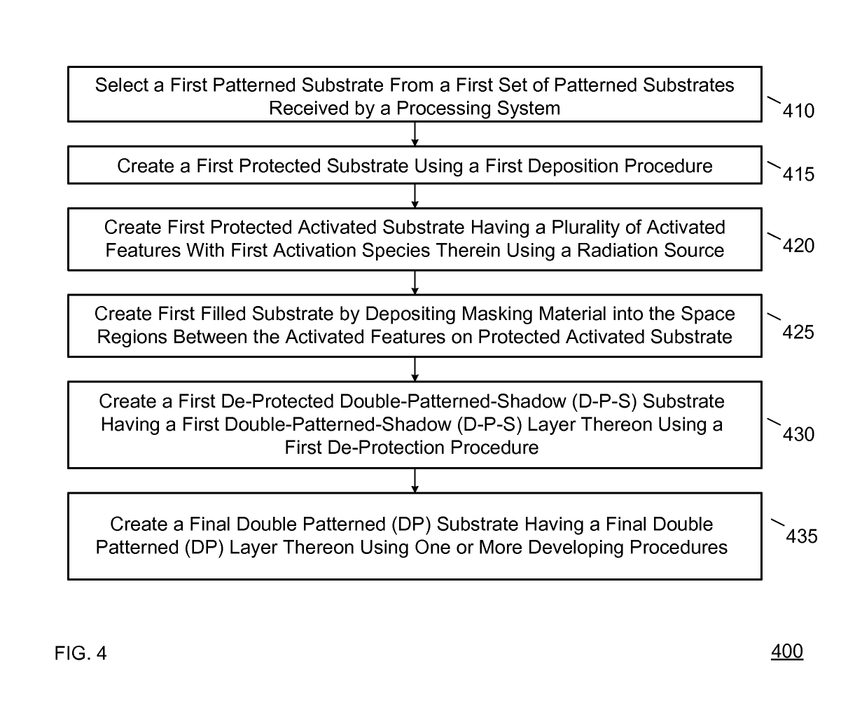

FIG. 4 shows an exemplary flow diagram for a Double-Patterned Shadow (D-P-S) procedure in accordance with embodiments of the invention.

In 410, a first set of substrates can be received using one or more of the cassettes (13, FIGS. 1-3) in the load/unload section (10, FIGS. 1-3) of the processing system (1, FIGS. 1-3). The load/unload section (10, FIGS. 1-3) has a cassette table (20, FIGS. 1-3) on which cassettes (13, FIGS. 1-3), each storing a plurality of semiconductor substrates (14, FIGS. 1-3), are loaded and unloaded from the processing system (1, FIGS. 1-3), and substrate data can be received for the one or more substrates (14, FIGS. 1-3). Alternatively, a substrate can be received by one or more external transfer subsystems. During some (D-P-S) procedures, the first set of substrates can include patterned substrates, and a first patterned substrate can be selected for processing. The substrate data can include historical and/or real-time data. Operational state data can be established for one or more of the substrates, and the operational state data can include site data, location-dependent data, chip-dependent data, and/or die-dependent data.

In some embodiments, the first patterned substrate (510, FIG. 5A) can be selected from the first set of substrates received by the processing system (1, FIGS. 1-3), and the first patterned substrate (510, FIG. 5A) can include one or more substrate layers (501, FIG. 5A), one or more target layers (502, FIG. 5A) on top of the one or more substrate layers (501, FIG. 5A), and a first patterned layer (511, FIG. 5A) on top of the one or more target layers (502, FIG. 5A). The first patterned substrate (510, FIG. 5A) can include a plurality of first features (512, FIG. 5A) on the one or more target layers (502, FIG. 5A) and a plurality of first space regions (513, FIG. 5A) configured above the one or more target layers (502, FIG. 5A), and each of the first space regions (513, FIG. 5A) can be configured between two of the first features (512, FIG. 5A).

The substrate layers (501, FIG. 5A) can include semiconductor material. The target layers (502, FIG. 5A) can include semiconductor material, low-k dielectric material, ultra-low-k dielectric material, ceramic material, glass material, metallic material, resist material, filler material, doped material, un-doped material, stressed material, oxygen-containing material, nitrogen-containing material, carbon-containing material, anti-reflective coating (ARC) material, or bottom anti-reflective coating (BARC) material, or any combination thereof. For example, the semiconductor material can include Silicon (Si), Germanium (Ge), Gallium Arsenide (GaAr) material that can be stressed and/or doped. The first features (512, FIG. 5A) can include first masking material.

In some embodiments, a processing sequence can be determined for the first patterned substrate, and during some (D-P-S) processing sequences, measurement data can be obtained. For example, different (D-P-S) processing sequences can be determined for some of the patterned substrates. Alternatively, an external measurement procedure may be required. For example, (D-P-S) procedures can more easily be performed for parallel line structures and some memory array structures. In some alternate embodiments, one or more protection layers (not shown) can be created on the plurality of first features (512, FIG. 5A) on the first patterned substrate (510, FIG. 5A).

When a first (D-P-S) evaluation substrate is selected from the first set of (D-P-S) substrates, and the first (D-P-S) evaluation can have a plurality of first features (512, FIG. 5A) thereon, and first evaluation and/or measurement data can be obtained that includes measured signal data from at least one of the plurality of first features (512, FIG. 5A) on the first (D-P-S) substrate. In some procedures, best estimate signal data and associated best estimate structure can be selected from a library of (D-P-S) simulated and/or measurement signals and associated structures. For example, the signals may include diffraction signals and/or spectra, refraction signals and/or spectra, reflection signals and/or spectra, or transmission signals and/or spectra, or any combination thereof.

In some embodiments, the first features (512, FIG. 5A) can include mask structures, etched structures, doped structures, filled structures, semi-filled structures, damaged structures, dielectric structures, gate structures, gate electrode structures, gate stack structures, transistor structures, FinFET structures, CMOS structures, photoresist structures, periodic structures, alignment structures, trench structures, or via structures, array structures, grating structures, or any combination thereof. In addition, the (D-P-S) evaluation data can include intensity data, transmission data, absorption data, reflectance data, diffraction data, optical properties data, or image data, or any combination thereof.

In 415, a first protected substrate (520, FIG. 5B) can be created using the first patterned substrate (510, FIG. 5A). In some embodiments, a first protected patterned layer (521, FIG. 5B) can be established on the first protected substrate (520, FIG. 5B) by depositing one or more protection layers (503, 503′, FIG. 5B) on top of the “previously-unprotected” first patterned substrate (510, FIG. 5A), and thereby creating a plurality of first protected features (522, FIG. 5B) and a plurality of protected space regions (523, FIG. 5B) on the target layer (502, FIG. 5B) in the first protected substrate (520, FIG. 5B). The first protected substrate (520, FIG. 5B) can include the plurality of first protected features (522, FIG. 5B) having a first portion of a protection layer (503, FIG. 5B) configured thereon and a plurality of protected space regions (523, FIG. 5B) having a second portion of protection layer (503′, FIG. 5B) configured therein. For example, each of the protected space regions (523, FIG. 5B) can include a second portion of the protection layer (503′, FIG. 5B) that can be configured between two of the first protected features (522, FIG. 5B) on the target layer (502, FIG. 5B) in the first protected substrate (520, FIG. 5B).

In some embodiments, the first protected substrate (520, FIG. 5B) can be created by performing a first deposition procedure using one or more of the processing elements in the processing system (1, FIGS. 1-3). For example, a plurality of protected features (522, FIG. 5B) and a plurality of protected space regions (523, FIG. 5B) can be created at a first number of sites on the first protected substrate (520, FIG. 5B).

The first protected features (522, FIG. 5B) can comprise a first masking material that can be protected by a protection layer (503, FIG. 5B) that can include a second masking material. The first protected space regions (523, FIG. 5B) can include a protected target layer (502, FIG. 5B) that can be “protected” by the second portion of the protection layer (503′, FIG. 5B) that can include a second masking material.

In various examples, the first protected features (522, FIG. 5B) can comprise a first masking material that can include a first CAR material, a first NCAR material, a first dual-tone resist material, a first ARC material, a first TARC material, or a first BARC material, or any combination thereof. In addition, the first portion of the protection layer (503, FIG. 5B) and the second portion of the protection layer (503′, FIG. 5B) can comprise a second masking material that can include a second CAR material, a second NCAR material, a second dual-tone resist material, a second ARC material, a second TARC material, or a second BARC material, or any combination thereof. Alternatively, the second portions of the protection layer (503′, FIG. 5B) may be removed and/or altered in subsequent procedures.

One or more (D-P-S) evaluation procedures can be performed after the protected substrate (520, FIG. 5B) are created to establish and/or teach a protection recipe. In addition, one or more (D-P-S) evaluation procedures can be performed before the protected substrate (520, FIG. 5B) are created to correct and/or update a protection recipe.

In 420, a first protected activated substrate (530, FIG. 5C) can include an activated patterned layer (531, FIG. 5C) configured on the target layer (502, FIG. 5C). The first protected activated substrate (530, FIG. 5C) can include a plurality of protected activated features (532, FIG. 5C) that are “protected” by a first portion of the protection layers (503, FIG. 5C) and a plurality of protected space regions (533, FIG. 5C) that can be “protected” by a second portion of the protection layers (503′, FIG. 5C). For example, each of the protected space regions (533, FIG. 5C) can be configured on the target layer (502, FIG. 5C) and can be positioned between two of the protected activated features (532, FIG. 5C) on the first protected activated substrate (530, FIG. 5C).

In some embodiments, the protected activated features (532, FIG. 5C) can be created (activated) by “creating and/or activating” a plurality of first activation species (535, FIG. 5C) in each of the protected activated features (532, FIG. 5C) on the first protected activated substrate (530, FIG. 5C). For example, the first activation species (535, FIG. 5C) can be “created and/or activated” in each of protected activated features (532, FIG. 5C) by performing a first radiation exposure procedure using one or more of the processing elements in the processing system (1, FIGS. 1-3), and one or more protected activated features (532, FIG. 5C) can be created at a first number of sites on the first protected activated substrate (530, FIG. 5C).

In some examples, the first masking material in each of “previously-shown” protected features (522, FIG. 5B) can include at least one “un-activated” activation species that can be activated using a first radiation pattern 509a, thereby creating the plurality of first activation species (535, FIG. 5C) in the protected activated features (532, FIG. 5C) on the first protected activated substrate (530, FIG. 5C). In other examples, the first masking material in each of “previously-shown” protected features (522, FIG. 5B) can include at least one protected activation species that can be “de-protected” using the first radiation pattern 509a, thereby creating the plurality of first activation species (535, FIG. 5C). In still other examples, the first masking material in each of “previously-shown” protected features (522, FIG. 5B) can include at least one CAR that can be “de-protected” using the first radiation pattern 509a, thereby creating the plurality of first activation species (535, FIG. 5C).

After an exposure procedure has been performed, the protected activated features (532, FIG. 5C) can comprise “activated” first masking material that can be “activated” during the exposure procedure. The “activated” first masking material can include the first activation species (535, FIG. 5C), and the first activation species (535, FIG. 5C) can be “protected” by the first portion of the protection layer (503, FIG. 5C). The “protected non-activated” space regions (533, FIG. 5C) can include a target layer (502, FIG. 5C) that has been “previously-protected” by the second portion of the protection layer (503′, FIG. 5C). In addition, the first portion of the protection layer (503, FIG. 5C) and the second portion of the protection layer (503′, FIG. 5C) can include second masking material that can be configured to be selectively transparent to one or more wavelengths and/or one or more intensities that can be used in the exposure procedure when the first masking material in the first features is activated.

In some embodiments, one or more (D-P-S) evaluation procedures can be performed before the first protected activated substrate (530, FIG. 5C) is created to establish and/or teach an activation recipe. In other embodiments, one or more (D-P-S) evaluation procedures can be performed during and/or after the first protected activated substrate (530, FIG. 5C) is created to correct and/or update an activation recipe.

In 425, a first filled substrate (540, FIG. 5D) having a first filled patterned layer (541, FIG. 5D) can be created by depositing in a first fill procedure a third masking material into the “open areas” in the plurality of “non-activated” protected space regions (533, FIG. 5C) on the “previously-shown” first protected activated substrate (530, FIG. 5C), thereby creating a plurality of first fill layers (543, FIG. 5D) between the plurality of “previously-activated” features (542, FIG. 5D) on the first filled substrates (540, FIG. 5D).

The first filled substrate (540, FIG. 5D) can include a plurality of first “previously-activated” features (542, FIG. 5D) encased in a first portion of the protection layer (503, FIG. 5D), and a plurality of first fill layers (543, FIG. 5D) deposited on a second portion of the protection layer (503′, FIG. 5D). For example, the first “previously-activated” features (542, FIG. 5D), the first portion of the protection layer (503, FIG. 5D), the plurality of first fill layers (543, FIG. 5D), and the second portions of the protection layer (503′, FIG. 5D) can be configured above the target layer (502, FIG. 5D) on the first filled substrate (540, FIG. 5D), and each of the first fill layers (543, FIG. 5D) can be configured between two of the first “previously-activated” features (542, FIG. 5D) on the first filled substrate (540, FIG. 5D). In addition, the first “previously-activated” features (542, FIG. 5D) can include the previously created activation species (545, FIG. 5D); the first portions of the protection layer (503, FIG. 5D) and the second portions of the protection layer (503′, FIG. 5D) can include second masking material; and the first fill layers (543, FIG. 5D) can include a third masking material layer.

In some embodiments, the first filled substrate (540, FIG. 5D) can be created by performing one or more fill (deposition) procedures using one or more of the processing units in the processing system (1, FIGS. 1-3), and a plurality of first fill layers (543, FIG. 5D) can be created at a first number of sites on each of the first filled substrates (540, FIG. 5D). For example, the third masking material deposited in the plurality of first fill layers (543, FIG. 5D) can include a third activation species (not shown) that can be activated at a later time using a radiation procedure and/or a thermal procedure. In addition, one or more dispensing procedures may be performed at later time to activate and/or enhance the activation of the third masking material, and the dispensing procedures may include a radiation procedure and/or a thermal procedure.

In 430, a first de-protected Double-Patterned-Shadow (D-P-S) substrate (550, FIG. 5E) having a first de-protected Double-Patterned-Shadow (D-P-S) layer (551, FIG. 5E) thereon can be created using first “de-protection” procedures.

In some embodiments, the first de-protected (D-P-S) substrate (550, FIG. 5E) can include a plurality of protected diffusion features (552, FIG. 5E) that can be “protected” by the first portions of the protection layer (503, FIG. 5E) that are covering the protected diffusion features (552, FIG. 5E). A first de-protection region (554, FIG. 5E), a self-aligned second (D-P-S) feature (557, FIG. 5E), and a second portion of the protection layer (503′, FIG. 5E) can be configured above the target layer (502, FIG. 5E) and can be positioned between two of the protected diffusion features (552, FIG. 5E).

The first de-protected (D-P-S) substrate (550, FIG. 5E) can be created by activating and/or diffusing the plurality of first activation species (555, FIG. 5E) in the protected diffusion features (552, FIG. 5E) through some of the first portions of the protection layer (503, FIG. 5E), by activating and/or diffusing a third de-protecting species (556, FIG. 5E) in the third masking material in the plurality of de-protection regions (554, FIG. 5E), by activating one or more additional activation species in the second masking material in the second portions of protection layer (503′, FIG. 5E), and by not activating any activation species in the second masking material in the first portions of protection layer (503, FIG. 5E). The protected diffusion features (552, FIG. 5E), the self-aligned second (D-P-S) features (557, FIG. 5E), and the de-protection regions (554, FIG. 5E) can be created at a first number of sites on the first (D-P-S) substrate (550, FIG. 5E).

In some embodiments, the protected diffusion features (552, FIG. 5E) can represent “desired” first double pattern (DP) features; the plurality of self-aligned second (D-P-S) features (557, FIG. 5E) can represent “desired” second double pattern (DP) features; and the plurality of de-protection regions (554, FIG. 5E) can represent “desired” double pattern (DP) space regions between the first and second double pattern (DP) features. In addition, the first de-protected (D-P-S) layer (551, FIG. 5E) may be configured differently. Alternatively, some sidewall angle (SWA) regions (not shown) may be present. In addition, different radiation procedures having different wavelengths may be used to activate and/or de-activate different activation and/or de-protecting species, and different dispensing procedures having different liquids and/or gases may be used to activate and/or de-activate different activation and/or de-protecting species.

During some de-protecting procedures, the protected diffusion features (552, FIG. 5E) can comprise “de-activating” first masking material that can be “de-activated” using the second radiation pattern (509b, FIG. 5E). For example, the second radiation pattern (509b, FIG. 5E) can include a second set of wavelengths, and the protection layer 503 can be substantially transparent to one or more of the second set of wavelengths. In addition, the “previously-created” first activation species (555, FIG. 5E) can be moved through the “previously-created” protection layer (503, FIG. 5E) that can include a second masking material, and the second masking material can be “selectivity-permeable” to the first activation species (555, FIG. 5E).

The de-protection regions (554, FIG. 5E) can comprise “de-protectable” third masking material that can be “de-protected” by moving the “newly-created” third de-protecting species (556, FIG. 5E) through the “previously-deposited” fill layers (543, FIG. 5D) using the second radiation pattern (509b, FIG. 5E). For example, the “de-protectable” third masking material can be “selectively-de-protectable” to the third de-protecting species (556, FIG. 5E). In some examples, the de-protection regions (554, FIG. 5E) can comprise “de-protectable” protection layer material that can be “de-protected” by moving the “newly-created” third de-protecting species (556, FIG. 5E) through some of the “previously-deposited” protection layer (503, FIG. 5E) using the second radiation pattern (509b, FIG. 5E). Some of the second masking material in the “previously-deposited” protection layer (503, FIG. 5E) can include some “de-protectable” second masking material, and this “de-protectable” second masking material can be “selectively-de-protectable” to the third de-protecting species (556, FIG. 5E).

The self-aligned second (D-P-S) features (557, FIG. 5E) can comprise “protected” third masking material that can remain “protected” by not moving the “newly-created” third de-protecting species (556, FIG. 5E) through this “protected” third masking material.

During other de-protecting procedures, the second radiation pattern (509b, FIG. 5E) and at least one thermal procedure can be used. In addition, different intensities and/or wavelengths can be used to activate and/or de-activate different first activation species (555, FIG. 5E) and/or third de-protecting species (556, FIG. 5E). During still other de-protecting procedures, at least one thermal procedure can be used. In addition, different temperatures and/or pressures can be used to activate and/or de-activate different first activation species (555, FIG. 5E) and/or third de-protecting species (556, FIG. 5E). Additionally, one or more dispensing processes may be used during the de-protecting procedures to provide additional activation and/or de-protecting species.

In various embodiments, the exposure procedure can include a flood exposure procedure, an infrared (IR) exposure procedure, an ultraviolet (UV) exposure procedure, an extreme ultraviolet (EUV) exposure procedure, or an exposure procedures using visible light, or any combination thereof.

In 435, a final Double Patterned (DP) substrate (560, FIG. 5F) having a final Double Patterned (DP) layer (561, FIG. 5F) thereon can be created by performing at least one developing procedure using one or more of the processing elements in the processing system (1, FIGS. 1-3). The final DP substrate (560, FIG. 5F) can include a plurality of final first Double Patterned (DP) features (562, FIG. 5F), a plurality of final second Double Patterned (DP) features (567, FIG. 5F), and a plurality of final (DP) spaces (564, FIG. 5F) configured on the target layer (502, FIG. 5F). In some embodiments, the final developing procedures can include: establishing the plurality of final first DP features (562, FIG. 5F) by removing the protection layer from the protected diffusion features using a first developing procedure; establishing the plurality of final DP space regions (564, FIG. 5F) by removing the de-protection regions using a second developing procedure; and establishing a plurality of final second DP features (567, FIG. 5F) using the self-aligned second (D-P-S) features, wherein each final DP space region is created adjacent to each final first DP feature, and each final second DP feature being created between two final DP space regions.

In other embodiments, the de-protected third masking material in the “previously shown” de-protection regions (554, FIG. 5E) can be developable and can be removed using one or more wet developing procedures. In addition, the first portion of the protection layer (503, FIG. 5E) and/or the second portion of the protection layer (503′, FIG. 5E) can be removed during the developing procedures. Alternatively, some of the first portion of the protection layer (503, FIG. 5E) and/or some of the second portion of the protection layer (503′, FIG. 5E) may not be removed during the developing procedures.

In some embodiments, evaluation and/or data analysis procedures can be performed to determine if the steps in procedure 400 were performed correctly. When the steps in procedure 400 were performed correctly, post-processing procedures (not shown) can be performed, and when the steps in procedure 400 were not performed correctly, corrective actions (not shown) can be performed. For example, tool data, chamber data, particle data, image data, process data, and/or fault data may be analyzed. In addition, the post processing procedures and/or the corrective actions can include re-measuring procedures, re-evaluating procedures, re-working procedures, and/or repeating one or more of the steps in the processing sequence.

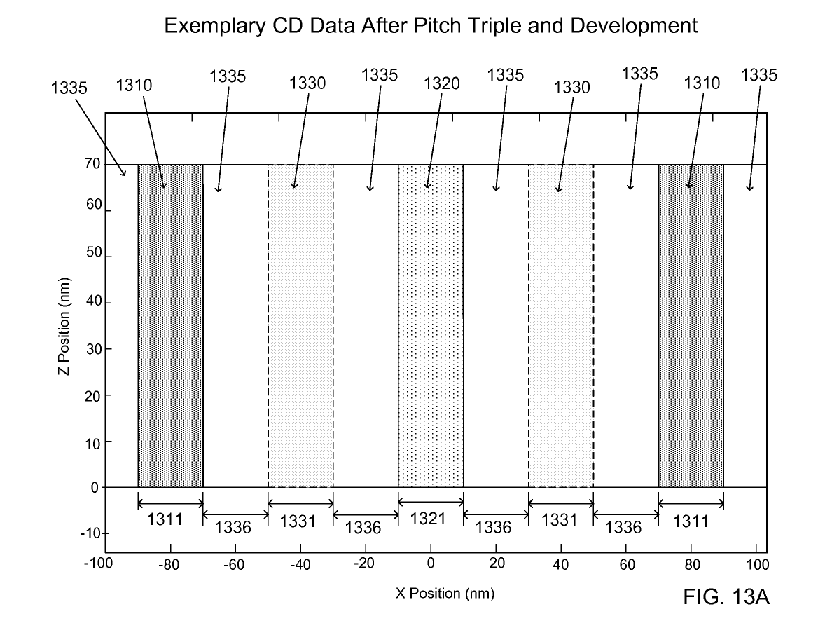

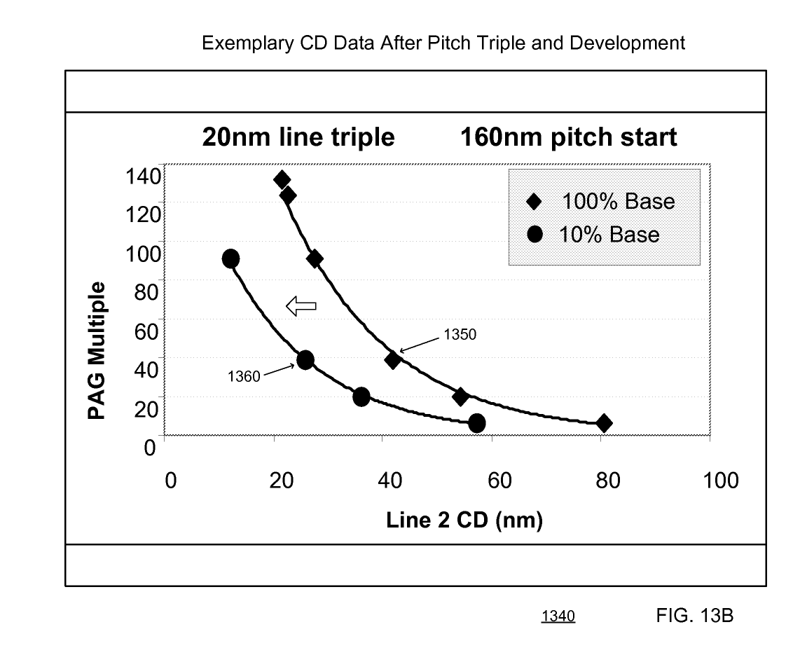

In other embodiments, procedure 400 can be repeated during triple patterning procedures, and the triple patterns shown in FIG. 13A can be obtained.

FIGS. 5A-5F illustrate a simplified representation of exemplary steps in a Double-Patterning-Shadow (D-P-S) procedure in accordance with embodiments of the invention. In FIGS. 5A-5F, substrates (510-560) are shown that include one or more substrate layers 501, and one or more target layers 502. Alternatively, a different set of substrates may be used that may be configured differently.

In various examples, the substrate layers 501 can have thicknesses 501a that can vary from about 10 nm to about 500 nm; and the target layers 502 can have thicknesses 502a that can vary from about 10 nm to about 50 nm.

The substrate layers 501 can include semiconductor material, carbon material, dielectric material, glass material, ceramic material, metallic material, implanted material, oxygen-containing material, or nitrogen-containing material, or a combination thereof. The target layers 502 can include semiconductor material, low-k dielectric material, ultra-low-k dielectric material, ceramic material, glass material, metallic material, resist material, filler material, doped material, un-doped material, strained-material, carbon-containing material, oxygen-containing material, nitrogen-containing material, anti-reflective coating (ARC) material, or bottom anti-reflective coating (BARC) material, implanted material, or planarization material, or any combination thereof.

FIG. 5A illustrates a first patterned substrate 510 having one or more substrate layers 501, one or more target layers 502, and a first patterned layer 511. The first patterned layer 511 can include a plurality of first features 512 separated by a plurality of first space regions 513. The first features 512 can comprise a first masking material that can include chemically amplified resist (CAR) material, non-chemically amplified resist (NCAR) material, dual-tone resist material, anti-reflective coating (ARC) material, top anti-reflective coating (TARC) material, or bottom anti-reflective coating (BARC) material, or any combination thereof.

In other embodiments, the first masking material in the first features 512 can include: a polymer resin, a non-photoacid generator (NPAG) to provide sensitivity to a non-optical activation source, a dissolution inhibitor to provide a solubility switch before and after activation, and one or more components to modify the developing properties of the material after exposure to a light source having one or more wavelengths. For example, dissolution inhibitors may be oligomers of an acid-labile protected monomer, and the non-optical activation sources can include chemical activators, electrical activators, thermal activators, and/or pressure activators.

In various examples, the first features 512 can have “desired” thicknesses 512a that can vary from about 5 nm to about 500 nm; the first features 512 can have “desired” widths 512b that can vary from about 5 nm to about 500 nm; the first features 512 can have “desired” first periods 512c that can vary from about 15 nm to about 1500 nm; and the first space regions 513 can have “desired” space widths 513b that can vary from about 15 nm to about 1500 nm.

FIG. 5B illustrates a protected substrate 520 having one or more substrate layers 501, one or more target layers 502, and a protected patterned layer 521. The protected substrate 520 can include a plurality of protected features 522 separated by a plurality of protected space regions 523 that can be configured on a target layer 502. The protected features 522 can be “protected” using first portions of a protection layer 503, and the protected space regions 523 can be “protected” using second portion of a protection layer 503′.

In some embodiments, the first protected substrate 520 can be created by performing a first deposition procedure using one or more of the processing elements in the processing system (1, FIGS. 1-3). For example, a plurality of protected features 522 and a plurality of protected space regions 523 can be created at a first number of sites on the first protected substrate 520.

The protected features 522 can comprise “protected” first masking material that can include chemically amplified resist (CAR) material, non-chemically amplified resist (NCAR) material, dual-tone resist material, anti-reflective coating (ARC) material, top anti-reflective coating (TARC) material, or bottom anti-reflective coating (BARC) material, or any combination thereof.

The first portions of protection layer 503 and the second portions of protection layer 503′ can comprise second masking material that can include second CAR material, second NCAR material, second dual-tone resist material, second ARC material, second TARC material, or second BARC material, or any combination thereof.

In various examples, the protected features 522 can have thicknesses 522a that can vary from about 5 nm to about 500 nm; the protected features 522 can have widths 522b that can vary from about 5 nm to about 500 nm; the protected features 522 can have a first period 522c that can vary from about 15 nm to about 1500 nm; and the protected space regions 523 can have a space width 523b that can vary from about 15 nm to about 1500 nm. In addition, the first and second protection layers (503 and 503′) can have thicknesses (503a and 503′a) that can vary from about 2 nm to about 20 nm; the first protection layer 503 can have widths 503b that can vary from about 5 nm to about 50 nm.

FIG. 5C illustrates a first protected activated substrate 530 having one or more substrate layers 501, one or more target layers 502, and an activated patterned layer 531. The first protected activated substrate 530 can include a plurality of protected activated features 532 and a plurality of “protected non-activated” space regions 533 configured above a target layer 502. The protected activated features 532 can be “protected” by a first portion of the protection layer 503, and the “protected non-activated” space regions 523 can be “protected” by a second portion of the protection layer 503′.

In some embodiments, a first protected activated substrate 530 can be created by performing a first radiation procedure using one or more of the processing elements in the processing system (1, FIGS. 1-3). For example, the protected activated features 532 and the “protected non-activated” space regions 533 can be created at a first number of sites on the first protected activated substrate 530.

The protected activated features 532 can include a modified first masking material that has been activated (modified) by a first radiation pattern 509a. For example, the first radiation pattern 509a can include a first set of wavelengths and the protection layer 503 can be substantially transparent to one or more of the first set of wavelengths. In addition, the protected activated features 532 can include activated (modified) CAR material, activated (modified) NCAR material, activated (modified) dual-tone resist material, activated (modified) ARC material, activated (modified) TARC material, or activated (modified) BARC material, or any combination thereof.

In some embodiments, a first radiation pattern 509a can be used to create a plurality of first activation species 535 in the protected activated features 532. In other embodiments, a first radiation pattern 509a can be used with one or more thermal procedures to create a plurality of first activation species 535 in the protected activated features 532. In still other embodiments, a one or more thermal procedures can be used to create a plurality of first activation species 535 in the protected activated features 532. In various procedures, the first activation species 535 can include one or more chemically-amplified negative components, or one or more chemically-amplified positive components, or any combination thereof. In other examples, the first activation species 535 can include one or more chemically-amplified acid components, or one or more chemically-amplified base components, or any combination thereof.

In various examples, the protected activated features 532 can have thicknesses 532a that can vary from about 5 nm to about 500 nm; the protected activated features 532 can have widths 532b that can vary from about 5 nm to about 500 nm; the protected activated features 532 can have a first period 532c that can vary from about 15 nm to about 1500 nm; and the “protected non-activated” space regions 533 can have a space width 533b that can vary from about 15 nm to about 1500 nm. In addition, the first and second protection layers (503 and 503′) can have dimensions that are not affected by the exposure procedure.

FIG. 5D illustrates a first filled substrate 540 having one or more substrate layers 501, one or more target layers 502, and a filled patterned layer 541. The first filled substrate 540 can include a plurality of “previously-activated” features 542 separated by a plurality of first fill layers 543. The “previously-activated” features 542 can include a first masking material that has been “previously-activated” (modified) using the first radiation pattern 509a. For example, the “previously-activated” first masking material can include “previously-activated” CAR material, “previously-activated” NCAR material, “previously-activated” dual-tone resist material, “previously-activated” ARC material, “previously-activated” TARC material, or “previously-activated” BARC material, or any combination thereof. The first fill layers 543 can include third masking material that can be deposited on top of the second protection layer 503′ during one or more deposition procedures, and the third masking material can include additional CAR material, additional NCAR material, additional dual-tone resist material, additional ARC material, additional TARC material, or additional BARC material, or any combination thereof.

In various examples, the “previously-activated” features 542 can have thicknesses 542a that can vary from about 5 nm to about 500 nm; the “previously-activated” features 542 can have widths 542b that can vary from about 5 nm to about 500 nm; the “previously-activated” features 542 can have periods 542c that can vary from about 15 nm to about 1500 nm; the first fill layers 543 can have a fill thickness 543a that can vary from about 5 nm to about 500 nm; and the first fill layers 543 can have a fill width 543b that can vary from about 15 nm to about 1500 nm.

FIG. 5E illustrates a first de-protected double-patterned-shadow (D-P-S) substrate 550 having one or more substrate layers 501, one or more target layers 502, and a first de-protected (D-P-S) layer 551. The first de-protected (D-P-S) substrate 550 can include a plurality of protected diffusion features 552; a plurality of self-aligned second (D-P-S) features 557 that can be “non-activated” and therefore “un-developable”; and two sets of de-protection regions 554 that can be developable and that can surround each of self-aligned second (D-P-S) features 557. For example, the de-protection regions 554 can be de-protected by diffusing (moving) the first activation species 555 from the protected diffusion features 552 through the first portion of the protection layer 503 into the two sets of de-protection regions 554. When the first activation species 555 diffuses (moves) into the third masking material in the plurality of first fill layers, a third de-protecting species 556 can be activated in the third masking material and the third de-protecting species 556 can diffuse (move) through the third masking material, thereby de-protecting the third masking material and creating the two sets of de-protection regions 554 having developable material therein.

The protected diffusion features 552 can include first masking material that is being completely or partially “de-activated” (depleted) and can include “de-activatable” CAR material, “de-activatable” NCAR material, “de-activatable” dual-tone resist material, “de-activatable” ARC material, “de-activatable” TARC material, or “de-activatable” BARC material, or any combination thereof.

In some (D-P-S) de-protecting procedures, the two sets of de-protection regions 554 can include de-protected material, and the de-protected material can include de-protected CAR material, de-protected NCAR material, de-protected dual-tone resist material, de-protected ARC material, de-protected TARC material, or de-protected BARC material, or any combination thereof. In other (D-P-S) de-protecting procedures, the two sets of de-protection regions 554 can include de-blocked material, and the de-blocked material can include de-blocked CAR material, de-blocked NCAR material, de-blocked dual-tone resist material, de-blocked ARC material, de-blocked TARC material, or de-blocked BARC material, or any combination thereof.

In various examples, the protected diffusion features 552 can have thicknesses 552a that can vary from about 5 nm to about 500 nm; the protected diffusion features 552 can have widths 552b that can vary from about 5 nm to about 500 nm; the protected diffusion features 552 can have periods 552c that can vary from about 15 nm to about 1500 nm; the de-protection regions 554 can have thicknesses 554a that can vary from about 5 nm to about 500 nm; the de-protection regions 554 can have widths 554b that can vary from about 5 nm to about 500 nm; the self-aligned second (D-P-S) features 557 can have a feature thickness 557a that can vary from about 5 nm to about 500 nm; the self-aligned second (D-P-S) features 557 can have feature widths 557b that can vary from about 5 nm to about 500 nm; and the self-aligned second (D-P-S) 557 can have periods 557c that can vary from about 15 nm to about 1500 nm.

FIG. 5F illustrates a final Double Patterned (DP) substrate 560 having one or more substrate layers 501, one or more target layers 502, and a final Double Patterned (DP) layer 561. The final DP substrate 560 can include a plurality of final first DP features 562, a plurality of final second DP features 567, and two sets of equal final DP space regions 564 configured on the target layer 502. For example, the two sets of final DP space regions 564 can be created by removing the two sets of de-protection regions (554, FIG. 5E), the first portion of the protection layer (503, FIG. 5E), and the second portion of the protection layer (503′, FIG. 5E) using one or more developing procedures.

In various examples, the final first DP features 562 can have a first DP feature thickness 562a that can vary from about 5 nm to about 500 nm; the final first DP feature 562 can have a first DP feature width 562b that can vary from about 5 nm to about 500 nm; the final first DP feature 562 can have a first DP period 562c that can vary from about 15 nm to about 1500 nm; the final DP space regions 564 can have widths 564b that can vary from about 5 nm to about 500 nm; the final second DP features 567 can have second DP feature thicknesses 567a that can vary from about 5 nm to about 500 nm; the final second DP features 567 can have second DP feature widths 567b that can vary from about 5 nm to about 500 nm and the final second DP features 567 can have second DP feature periods 567c that can vary from about 15 nm to about 1500 nm.

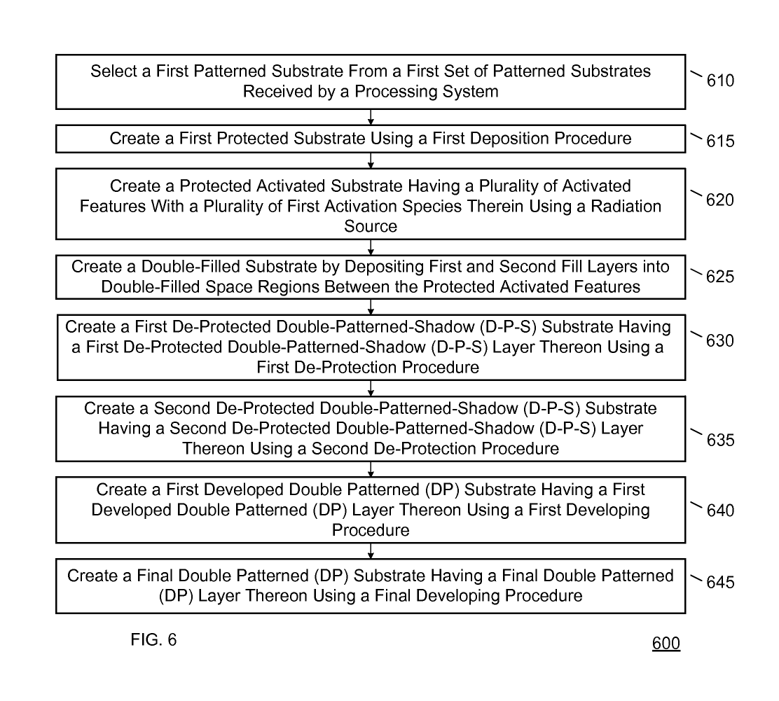

FIG. 6 shows another exemplary flow diagram for a Double-Patterned Shadow (D-P-S) procedure in accordance with embodiments of the invention.

In 610, a first set of substrates can be received using one or more of the cassettes (13, FIGS. 1-3) in the load/unload section (10, FIGS. 1-3) of the processing system (1, FIGS. 1-3). The load/unload section (10, FIGS. 1-3) has a cassette table (20, FIGS. 1-3) on which cassettes (13, FIGS. 1-3), each storing a plurality of semiconductor substrates (14, FIGS. 1-3), are loaded and unloaded from the processing system (1, FIGS. 1-3), and substrate data can be received for the one or more substrates (14, FIGS. 1-3). Alternatively, a substrate can be received by one or more external transfer subsystems. During some (D-P-S) procedures, the first set of substrates can include patterned substrates, and a first patterned substrate can be selected for processing. The substrate data can include historical and/or real-time data. In addition, operational state data can be established for one or more of the substrates, and the operational state data can include site data, chip-dependent data, and/or die-dependent data.

In some embodiments, the first patterned substrate (710, FIG. 7A) can be selected from the first set of substrates received by the processing system (1, FIGS. 1-3), and the first patterned substrate (710, FIG. 7A) can include one or more substrate layers (701, FIG. 7A), one or more target layers (702, FIG. 7A) on top of the one or more substrate layers (701, FIG. 7A), and a first patterned layer (711, FIG. 7A) on top of the one or more target layers (702, FIG. 7A). The first patterned layer (711, FIG. 7A) can include a plurality of first features (712, FIG. 7A) and a plurality of first space regions (713, FIG. 7A), and each of the first space regions (713, FIG. 7A) can be configured between two of the first features (712, FIG. 7A).

The substrate layers (701, FIG. 7A) can include semiconductor material. The target layers (702, FIG. 7A) can include semiconductor material, low-k dielectric material, ultra-low-k dielectric material, ceramic material, glass material, metallic material, resist material, filler material, doped material, un-doped material, stressed material, oxygen-containing material, nitrogen-containing material, carbon-containing material, anti-reflective coating (ARC) material, or bottom anti-reflective coating (BARC) material, or any combination thereof. For example, the semiconductor material can include Silicon (Si), Germanium (Ge), Gallium Arsenide (GaAr) material that can be stressed and/or doped. The first features (712, FIG. 7A) can include first masking material.

In some embodiments, a processing sequence can be determined for the first patterned substrate, and during some (D-P-S) processing sequences, measurement data can be obtained. For example, different (D-P-S) processing sequences can be determined for some of the patterned substrates. Alternatively, an external measurement procedure may be required. For example, (D-P-S) procedures can more easily be performed for parallel line structures and some memory array structures.

When a first (D-P-S) evaluation substrate is selected from the first set of (D-P-S) substrates, and the first (D-P-S) evaluation can have a plurality of first features (712, FIG. 7A) thereon, and first evaluation and/or measurement data can be obtained that includes measured signal data from at least one of the plurality of first features (712, FIG. 7A) on the first (D-P-S) substrate. In some procedures, best estimate signal data and associated best estimate structure can be selected from a library of (D-P-S) measurement signals and associated structures. For example, the signals may include diffraction signals and/or spectra, refraction signals and/or spectra, reflection signals and/or spectra, or transmission signals and/or spectra, or any combination thereof.

In some embodiments, the first features (712, FIG. 7A) can include mask structures, etched structures, doped structures, filled structures, semi-filled structures, damaged structures, dielectric structures, gate structures, gate electrode structures, gate stack structures, transistor structures, FinFET structures, CMOS structures, photoresist structures, periodic structures, alignment structures, trench structures, or via structures, array structures, grating structures, or any combination thereof. In addition, the (D-P-S) evaluation data can include intensity data, transmission data, absorption data, reflectance data, diffraction data, optical properties data, or image data, or any combination thereof.

In 615, a first protected substrate (720, FIG. 7B) can be created using the first patterned substrate (710, FIG. 7A). In some embodiments, a first protected patterned layer (721, FIG. 7B) can be established on the first protected substrate (720, FIG. 7B) by depositing one or more protection layers (703, 703′, FIG. 7B) on top of the “previously-unprotected” first patterned substrate (710, FIG. 7A), and thereby creating a plurality of protected features (722, FIG. 7B) and a plurality of protected space regions (723, FIG. 7B) on the target layer (702, FIG. 7B) in the first protected substrate (720, FIG. 7B). The first protected substrate (720, FIG. 7B) can include the plurality of protected features (722, FIG. 7B) having a first portion of a protection layer (703, FIG. 7B) configured thereon and a plurality of protected space regions (723, FIG. 7B) having a second portion of protection layer (703′, FIG. 7B) configured therein. For example, each of the protected space regions (723, FIG. 7B) can include a second portion of the protection layer (703′, FIG. 7B) that can be configured between two of the protected features (722, FIG. 7B) on the target layer (702, FIG. 7B) in the first protected substrate (720, FIG. 7B).

In some embodiments, the first protected substrate (720, FIG. 7B) can be created by performing a first deposition procedure using one or more of the processing elements in the processing system (1, FIGS. 1-3). For example, a plurality of protected features (722, FIG. 7B) and a plurality of protected space regions (723, FIG. 7B) can be created at a first number of sites on the first protected substrate (720, FIG. 7B).

The protected features (722, FIG. 7B) can comprise a first masking material that can be protected by a protection layer (703, FIG. 7B) that can include a second masking material. The protected space regions (723, FIG. 7B) can include a protected target layer (702, FIG. 7B) that can be “protected” by the second portion of the protection layer (703′, FIG. 7B) that can include a second masking material.

In various examples, the protected features (722, FIG. 7B) can comprise a first masking material that can include a first CAR material, a first NCAR material, a first dual-tone resist material, a first ARC material, a first TARC material, or a first BARC material, or any combination thereof. In addition, the first portion of the protection layer (703, FIG. 7B) and the second portion of the protection layer (703′, FIG. 7B) can comprise a second masking material that can include a second CAR material, a second NCAR material, a second dual-tone resist material, a second ARC material, a second TARC material, or a second BARC material, or any combination thereof. In alternate embodiments, the second portions of the protection layer (703′, FIG. 7B) may be removed and/or altered in subsequent procedures.

In some embodiments, one or more (D-P-S) evaluation procedures can be performed after one or more first protected substrates (720, FIG. 7B) is created to establish and/or teach a protection recipe. In other embodiments, one or more (D-P-S) evaluation procedures can be performed before the first protected substrate (720, FIG. 7B) are created to correct and/or update a protection recipe.

In 620, a first protected activated substrate (730, FIG. 7C) can include an activated patterned layer (731, FIG. 7C) configured on the target layer (702, FIG. 7C). The first protected activated substrate (730, FIG. 7C) can include a plurality of protected activated features (732, FIG. 7C) that are “protected” by a first portion of the protection layers (703, FIG. 7C) and a plurality of protected space regions (733, FIG. 7C) that can be “protected” by a second portion of the protection layers (703′, FIG. 7C). For example, each of the protected space regions (733, FIG. 7C) can be configured on the target layer (702, FIG. 7C) and can be positioned between two of the protected activated features (732, FIG. 7C) on the first protected activated substrate (730, FIG. 7C).

In some embodiments, the protected activated features (732, FIG. 7C) can be created (activated) by “activating” a plurality of first activation species (735, FIG. 7C) in each of the protected activated features (732, FIG. 7C) on the first protected activated substrate (730, FIG. 7C). For example, the first activation species (735, FIG. 7C) can be created (activated) in each of protected activated features (732, FIG. 7C) by performing a first radiation exposure procedure using one or more of the processing elements in the processing system (1, FIGS. 1-3), and protected activated features (732, FIG. 7C) can be created at a first number of sites on the first protected activated substrate (730, FIG. 7C).

In some examples, the first masking material in each of “previously-shown” protected features (722, FIG. 7B) can include at least one “un-activated” activation species that can be activated using a first radiation pattern 709a, thereby creating the plurality of first activation species (735, FIG. 7C) in the protected activated features (732, FIG. 7C) on the first protected activated substrate (730, FIG. 7C). In other examples, the first masking material in each of “previously-shown” protected features (722, FIG. 7B) can include at least one “protected activation species” that can be “de-protected” using the first radiation pattern 709a, thereby creating the plurality of first activation species (735, FIG. 7C). In still other examples, the first masking material in each of “previously-shown” protected features (722, FIG. 7B) can include at least one CAR that can be “de-protected” using the first radiation pattern 709a, thereby creating the first activation species (735, FIG. 7C).

After an exposure procedure has been performed, the protected activated features (732, FIG. 7C) can comprise “activated” first masking material that can be “activated” during the exposure procedure. The “activated” first masking material can include the first activation species (735, FIG. 7C), and the first activation species (735, FIG. 7C) can be protected by the first portion of the protection layer (703, FIG. 7C). The “protected non-activated”space regions (733, FIG. 7C) can include a target layer (702, FIG. 7C) that has been “previously-protected” by the second portion of the protection layer (703′, FIG. 7C). In addition, the first portion of the protection layer (703, FIG. 7C) and the second portion of the protection layer (703′, FIG. 7C) can include second masking material that can be configured to be selectively transparent to one or more wavelengths and/or one or more intensities that can be used in the exposure procedure when the first masking material in the first features is activated.

In addition, the one or more portions of the protection layer (703, FIG. 7C) can be removed before, during, and/or after the exposure procedure has been performed.

In some embodiments, one or more (D-P-S) evaluation procedures can be performed before the first protected activated substrate (730, FIG. 7C) are created to establish and/or teach an activation recipe. In other embodiments, one or more (D-P-S) evaluation procedures can be performed during and/or after the first protected activated substrate (730, FIG. 7C) are created to correct and/or update an activation recipe.

In 625, a first double-filled substrate (740, FIG. 7D) having a “doubly-filled” patterned layer (741, FIG. 7D) thereon can be created by performing one or more fill (deposition) procedures using one or more of the processing units in the processing system (1, FIGS. 1-3), and a first fill layers (743, FIG. 7D) and second fill layers (744, FIG. 7D) can be created at a first number of sites on each of the first double-filled substrates (740, FIG. 7D). For example, a first fill layer (743, FIG. 7D) and a second fill layer (744, FIG. 7D) can be deposited into the “open areas” in the plurality of “previously-protected” space regions (733, FIG. 7C), thereby creating a first fill layer (743, FIG. 7D) and a second fill layer (744, FIG. 7D) between the plurality of “previously-activated” features (742, FIG. 7D) on the first double-filled substrates (740, FIG. 7D).

The double-filled substrate (740, FIG. 7D) can include a plurality of first “previously-activated” features (742, FIG. 7D) encased in a protection layer (703, FIG. 7D) that can be configured on the target layer (702, FIG. 7D). In some embodiments, a first fill layer (743, FIG. 7D) and a second fill layer (744, FIG. 7D) can be configured between two of the first “previously-activated” features (742, FIG. 7D). Alternatively, a first fill layer (743, FIG. 7D), a second fill layer (744, FIG. 7D), and a portion of the protection layer (not shown) can be configured between two of the first “previously-activated” features (742, FIG. 7D). The first “previously-activated” features (742, FIG. 7D) can include the previously created activation species (745, FIG. 7D); the protection layer (703, FIG. 7D) can comprise a second masking material; the first fill layer (743, FIG. 7D) can comprise a third masking material; and a second fill layer (744, FIG. 7D) can comprise a fourth masking material.

The “previously-activated” features (742, FIG. 7D) can comprise activated first masking material that has been “previously-activated” using the first activation species (745, FIG. 7D) and has been “previously-protected” using the protection layer (703, FIG. 7D) that can include a second masking material. The first fill layer (743, FIG. 7D) can include a third masking material, and the second fill layer (744, FIG. 7D) can include fourth masking material. Alternatively, at least one of the target layers (702, FIG. 7D) may include at least one additional activation species (not shown).

In some embodiments, the third masking material deposited in the first fill layer (743, FIG. 7D) can include a third activation species (not shown) that can be activated at a later time using a dispensing process, an exposure (radiation) procedure, and/or a thermal procedure, and the fourth masking material deposited in the second fill layer (744, FIG. 7D) can include a fourth activation species (not shown) that can be activated at a later time using a dispensing process, an exposure (radiation) procedure, and/or a thermal procedure. Additionally, one or more dispensing and/or activation procedures may be performed after the third masking material is deposited and/or after the fourth masking material is deposited.

One or more (D-P-S) evaluation procedures can be performed before the first double-filled substrate (740, FIG. 7D) is created to establish and/or teach a “fill” recipe. In addition, one or more (D-P-S) evaluation procedures can be performed after the first double-filled substrate (740, FIG. 7D) is created to obtain defect and damage data.

In 630, a first de-protected double-patterned-shadow (D-P-S) substrate (750, FIG. 7E) having a first de-protected double-patterned-shadow (D-P-S) layer (751, FIG. 7E) thereon can be created using one or more first “de-protection” procedures. In some embodiments, the first de-protected (D-P-S) substrate (750, FIG. 7E) can include a plurality of protected diffusion features (752, FIG. 7E), a plurality of self-aligned features (757, FIG. 7E), a plurality of sidewall angle (SWA) regions (758, FIG. 7E), and a plurality of de-protection regions (753, FIG. 7E) that can be configured on a target layer (702, FIG. 7E). For example, the protected diffusion features (752, FIG. 7E) can represent “desired” first double pattern (DP) features; the self-aligned features (757, FIG. 7E) can represent “desired” second double pattern (DP) features; the SWA regions (758, FIG. 7E) can be used to establish SWA's that can vary from about 80 degrees to about 100 degrees, and the de-protection regions (753, FIG. 7E) can represent “desired” double pattern (DP) spaces between the first and second double pattern (DP) features. The protected diffusion features (752, FIG. 7E) can be “protected” by the protection layer (703, FIG. 7E) that is covering each of the protected diffusion features (752, FIG. 7E). Alternatively, the first de-protected (D-P-S) substrate (750, FIG. 7E) may be configured differently, and/or the SWA regions (758, FIG. 7E) may not be present.

The first de-protected (D-P-S) substrate (750, FIG. 7E) can be created by activating and/or diffusing the plurality of first activation species (755, FIG. 7E) in the plurality of protected diffusion features (752, FIG. 7E) through some of the protection layer (703, FIG. 7E), by activating and/or diffusing a third de-protecting species (756, FIG. 7E) in the third masking material in the plurality of second fill layers (754, FIG. 7E), by not activating the fourth masking material in the second fill layer (754, FIG. 7E), and by not activating any activation species in the second masking material in the protection layer (703, FIG. 7E). The protected diffusion features (752, FIG. 7E), the plurality of self-aligned features (757, FIG. 7E), and the plurality of second fill layers (754, FIG. 7E) can be created at a first number of sites on the first (D-P-S) substrate (750, FIG. 7E).

During some first de-protecting procedures, the second radiation pattern 709b can be used when the first de-protected (D-P-S) substrate (750, FIG. 7E) is being created, and the protected diffusion features (752, FIG. 7E) are being “de-activated”. The second radiation pattern 709b can cause the protected diffusion features (752, FIG. 7E) to begin a diffusion process in which the “previously-created” first activation species (755, FIG. 7E) diffuse (move) from the protected diffusion features (752, FIG. 7E) through the “previously-created” protection layer (703, FIG. 7E) into “de-protectable” third masking material in the de-protection regions (753, FIG. 7E). When the first activation species (755, FIG. 7E) diffuses (moves) into the “de-protectable” third masking material in the de-protection regions (753, FIG. 7E) a plurality of third de-protecting species (756, FIG. 7E) can be created and can diffuse (move) through the “de-protectable” third masking material in the de-protection regions (753, FIG. 7E) thereby deprotecting the “de-protectable” third masking material in the de-protection regions (753, FIG. 7E). For example, the protection layer (703, FIG. 7E) can include a second masking material, and the second masking material can be “selectivity-permeable” to the first activation species (755, FIG. 7E). In addition, the second radiation pattern 709b can include a second set of wavelengths and the protection layer 703 can be substantially transparent to one or more of the second set of wavelengths. Furthermore, the “de-protectable” third masking material can be “selectively-de-protectable” to the first activation species (755, FIG. 7E) and/or the third de-protecting species (756, FIG. 7E).

The “sacrificial” SWA regions (758, FIG. 7E) can comprise “first protected” third masking material that can remain protected by not moving the “newly-created” third de-protecting species (756, FIG. 7E) through this “first protected” third masking material. In addition, the self-aligned features (757, FIG. 7E) can comprise “second protected” third masking material that can remain “protected” by not moving the “newly-created” third de-protecting species (756, FIG. 7E) through this “second protected” third masking material.

The plurality of self-aligned features (757, FIG. 7E) can include third masking material that remains “protected” (un-developable). In addition, the second fill layer (754, FIG. 7E) can cover the de-protection regions (753, FIG. 7E), the “sacrificial” SWA regions (758, FIG. 7E), and “un-developable” self-aligned second (D-P-S) features (757, FIG. 7E), For example, the third masking material in the de-protection regions (753, FIG. 7E) can have changed into a de-protected (developable) state, and the fourth masking material in the second fill layer (754, FIG. 7E) can remain in a protected (non-developable) state. In addition, some portions of the second masking material in the protection layer (703, FIG. 7E) can remain in a protected (non-developable) state, and other portions of the second masking material in the protection layer (703, FIG. 7E) can change into a de-protected (developable) state.

During other first de-protecting procedures, the second radiation pattern (709b, FIG. 7E) and at least one thermal procedure can be used. In addition, different intensities and/or wavelengths can be used to activate and/or de-activate different first activation species (755, FIG. 7E) and/or third de-protecting species (756, FIG. 7E). During still other de-protecting procedures, at least one thermal procedure can be used. In addition, different temperatures and/or pressures can be used to activate and/or de-activate different first activation species (755, FIG. 7E) and/or third de-protecting species (756, FIG. 7E). Alternatively, one or more dispensing processes may be used during the de-protecting procedures to provide additional activation and/or de-protecting species.

In various embodiments, the exposure procedure can include a flood exposure procedure, an infrared (IR) exposure procedure, an ultraviolet (UV) exposure procedure, or an extreme ultraviolet (EUV) exposure procedure, or a visible light exposure procedure, or any combination thereof.

In 635, a second de-protected double-patterned-shadow (D-P-S) substrate (760, FIG. 7F) having a second de-protected double-patterned-shadow (D-P-S) layer (761, FIG. 7F) thereon can be created using second de-protecting procedures. In some embodiments, the second de-protected (D-P-S) substrate (760, FIG. 7F) can include a plurality of first (D-P-S) features (762, FIG. 7F) that are covered by the protection layer (703, FIG. 7F), a plurality of “un-developable” self-aligned second (D-P-S) features (767, FIG. 7F) surrounded by two de-protected sidewall angle (SWA) regions (768, FIG. 7F) that are being “de-protected”, and a plurality of de-protected space regions (763, FIG. 7F) configured between each of the first (D-P-S) features (762, FIG. 7F) and each of the “un-developable” self-aligned second (D-P-S) features (767, FIG. 7F). For example, the first (D-P-S) features (762, FIG. 7F) can represent “desired” first double pattern (DP) features; the plurality of “un-developable” self-aligned second (D-P-S) features (767, FIG. 7F) can represent “desired” second double pattern (DP) features; the two de-protected SWA regions (768, FIG. 7F) can be used to establish SWA's that can vary from about 80 degrees to about 100 degrees, and the two sets of de-protected space regions (763, FIG. 7F) can represent “desired” double pattern (DP) space regions between the first and second double pattern (DP) features. In addition, the second de-protected (D-P-S) layer (761, FIG. 7F) may be configured differently. Alternatively, the de-protected SWA regions (768, FIG. 7F) may not be present.

The first (D-P-S) features (762, FIG. 7F) can comprise “de-activated” first masking material that has been “de-activated” by removing some or all of the “previously-created”first activation species (755, FIG. 7E). Alternatively, the first (D-P-S) features (762, FIG. 7F) may include some of the “previously-created” first activation species (755, FIG. 7E). The “previously-created” protection layer (703, FIG. 7F) can include a second masking material, and the second masking material can remain “protected” and is not de-protected by the third radiation pattern (709c, FIG. 7F). Alternatively, some of the second masking material may be de-protected by the third radiation pattern (709c, FIG. 7F).

The de-protected space regions (763, FIG. 7F) can comprise “de-protected” third masking material that has been “de-protected” and can now include a “developable” third masking material. In some examples, the de-protected space regions (763, FIG. 7F) can also comprise some “de-protected” second masking material that has been de-protected during the second de-protecting procedure.

The second de-protected (D-P-S) layer (761, FIG. 7F) can be created by activating the plurality of fourth activation species (705, FIG. 7F) in the fourth masking material in the second fill layer (764, FIG. 7F), and activating a new de-protecting species (706, FIG. 7F) in the “previous-processed” third masking material in the de-protected SWA regions (768, FIG. 7F), and by not activating any activation species in the second masking material in the protection layer (703, FIG. 7F). For example, the “previous-processed” third masking material in the de-protected SWA regions (768, FIG. 7F) can be “selectively-deprotectable” to the new de-protecting species (706, FIG. 7F), and the third radiation pattern (709c, FIG. 7F) can be used to move the new de-protecting species (706, FIG. 7F) through the “previous-processed” third masking material, thereby creating the de-protected SWA regions (768, FIG. 7F).

During some second de-protecting procedures, the second fill layer (764, FIG. 7F) can comprise a plurality of fourth activation species (705, FIG. 7F) that can be activated using a third radiation pattern (709c, FIG. 7E). For example, the third radiation pattern 709c can include a third set of wavelengths, and the second fill layer (764, FIG. 7F) can be “selectively-activated” by one or more of the third set of wavelengths. In addition, the de-protected SWA regions (768, FIG. 7F) can comprise “de-protectable” third masking material that can be “de-protected” by moving the “newly-created” new de-protecting species (706, FIG. 7F) through this “de-protectable” third masking material using the third radiation pattern (709c, FIG. 7E). In addition, the “previously-created-self-aligned” second (D-P-S) features (767, FIG. 7F) can comprise “protected” third masking material that can remain “protected” by not moving the “newly-created” new de-protecting species (706, FIG. 7F) through this “protected” third masking material.

During other second de-protecting procedures, the third radiation pattern (709c, FIG. 7F) and at least one thermal procedure can be used. In addition, different intensities and/or wavelengths can be used to activate and/or de-activate different fourth activation species (705, FIG. 7F) and/or new de-protecting species (706, FIG. 7F). During still other de-protecting procedures, at least one thermal procedure can be used. In addition, different temperatures and/or pressures can be used to activate and/or de-activate different fourth activation species (705, FIG. 7F) and/or new de-protecting species (706, FIG. 7F). Alternatively, one or more dispensing procedures may be used during the de-protecting procedures to provide additional activation and/or de-protecting species.

For example, the second de-protecting (activation) procedures can continue until the de-protected SWA regions (768, FIG. 7F) have been correctly created. In addition, the second de-protecting (activation) procedures can continue until the correct sidewall angles have been achieved in de-protected SWA regions (768, FIG. 7F).

In 640, a first developed double patterned (DP) substrate (770, FIG. 7G) having a first developed double patterned (DP) layer (771, FIG. 7G) thereon can be created by performing at least one first developing procedure using one or more of the processing elements in the processing system (1, FIGS. 1-3). For example, the “previously-diffused” (de-activated/de-protected) fourth masking material in the second fill layer (764, FIG. 7F) can be removed during the first developing procedures.

In some embodiments, the first developed DP substrate (770, FIG. 7G) can include a plurality of non-developed first DP features (772, FIG. 7G), a plurality of developable space region (773, FIG. 7G), a plurality of developable SWA region (778, FIG. 7G), and a plurality of self-aligned second DP features (777, FIG. 7G) that can be configured on the target layer (702, FIG. 7G). For example, the non-developed first DP features (772, FIG. 7G) can be covered by the protection layer (703, FIG. 7G). In addition, a developable space region (773, FIG. 7G) and a developable SWA region (778, FIG. 7G) can be configured on both sides of each of the self-aligned second DP features (777, FIG. 7G). Alternatively, some portions of the protection layer (703, FIG. 7G), or some portions of the developable space regions (773, FIG. 7G), or some portions of the developable SWA regions (778, FIG. 7G) may also be removed during the developing procedures.

In 645, a final Double Patterned (DP) substrate (780, FIG. 7H) having a final Double Patterned (DP) layer (781, FIG. 7H) can be created by performing at least one additional developing procedure using one or more of the processing elements in the processing system (1, FIGS. 1-3). The final DP substrate (780, FIG. 7H) can include a plurality of final first Double Patterned (DP) features (782, FIG. 7H), a plurality of final second Double Patterned (DP) features (787, FIG. 7H), and a plurality of final Double Patterned (DP) spaces (783, FIG. 7H) configured on the target layer (702, FIG. 7G).

In some embodiments, the “previously-deprotected” third masking material in the developable space region (773, FIG. 7G) can be removed during the additional developing procedures; the developable (deprotected) third masking material in the developable SWA region (778, FIG. 7G) can be removed during the additional developing procedures; and the second masking material in the remaining portions of the protection layer (703, FIG. 7G) can be removed during the additional developing procedures.

In addition, evaluation and/or data analysis procedures can be performed to determine if the steps in procedure 600 were performed correctly. When the steps in procedure 600 were performed correctly, post-processing procedures (not shown) can be performed, and when the steps in procedure 600 were not performed correctly, corrective actions (not shown) can be performed. For example, system data, unit processing data, chamber data, particle data, image data, process data, and/or fault data may be analyzed. In addition, the post processing procedures and/or the corrective actions can include re-measuring procedures, re-evaluating procedures, re-working procedures, and/or repeating one or more of the steps in the processing sequence.

In other embodiments, procedure 600 can be repeated during triple patterning procedures, and the triple patterns shown in FIG. 13A can be obtained.

FIGS. 7A-7H illustrate another simplified representation of exemplary steps in a Double-Patterned-Shadow (D-P-S) procedure in accordance with embodiments of the invention. In FIGS. 7A-7H, substrates (710-780) are shown that includes one or more substrate layers 701 and one or more target layers 702. Alternatively, a different set of substrates may be used that may be configured differently.

In various examples, the substrate layers 701 can have thicknesses 701a that can vary from about 10 nm to about 100 nm, and the target layers 702 can have thicknesses 702a that can vary from about 10 nm to about 50 nm.

The substrate layers 701 can include semiconductor material, carbon material, dielectric material, glass material, ceramic material, metallic material, implanted material, oxygen-containing material, or nitrogen-containing material, or a combination thereof. The target layers 702 can include semiconductor material, low-k dielectric material, ultra-low-k dielectric material, ceramic material, glass material, metallic material, resist material, filler material, doped material, un-doped material, stressed material, strained-material, carbon-containing material, oxygen-containing material, nitrogen-containing material, anti-reflective coating (ARC) material, or bottom anti-reflective coating (BARC) material, implanted material, or planarization material, or any combination thereof.

FIG. 7A illustrates a first patterned substrate 710 having one or more substrate layers 701, one or more target layers 702, and a first patterned layer 711 on top of the one or more target layers 702. The first patterned layer 711 can include a plurality of “desired” first features 712 separated by a plurality of first space regions 713. The first features 712 can comprise a first masking material that can include chemically amplified resist (CAR) material, non-chemically amplified resist (NCAR) material, dual-tone resist material, anti-reflective coating (ARC) material, top anti-reflective coating (TARC) material, or bottom anti-reflective coating (BARC) material, or any combination thereof.

In other embodiments, the first masking material in the first features 712 can include: a polymer resin, a non-photoacid generator (NPAG) to provide sensitivity to a non-optical activation source, a dissolution inhibitor to provide a solubility switch before and after activation, and one or more components to modify the developing properties of the material after exposure to a light source having one or more wavelengths. For example, dissolution inhibitors may be oligomers of an acid-labile protected monomer, and the non-optical activation sources can include chemical activators, electrical activators, thermal activators, and/or pressure activators.

In various examples, the first features 712 can have “desired” thicknesses 712a that can vary from about 5 nm to about 500 nm; the first features 712 can have “desired” widths 712b that can vary from about 5 nm to about 500 nm; the first features 712 can have “desired” periods 712c that can vary from about 15 nm to about 1500 nm; and the first space regions 713 can have widths 713b that can vary from about 15 nm to about 1500 nm.

FIG. 7B illustrates a first protected substrate 720 having one or more substrate layers 701, one or more target layers 702, and a protected patterned layer 721 on top of the one or more target layers 702. The protected patterned layer 721 can include a plurality of protected features 722 separated by a plurality of protected space regions 723. The protected patterned layer 721 can include a protection layer 703 that can be used to establish the plurality of protected features 722 and that can be used to establish the plurality of protected space regions 723. Alternatively, the plurality of protected space regions 723 may not be required or may be configured differently.

In some embodiments, the first protected substrate 720 can be created by performing a first deposition procedure using one or more of the processing elements in the processing system (1, FIGS. 1-3). For example, a plurality of protected features 722 and a plurality of protected space regions 723 can be created at a first number of sites on the first protected substrate 720 during one or more deposition procedures.

The protected features 722 can comprise “protected” first masking material that can include chemically amplified resist (CAR) material, non-chemically amplified resist (NCAR) material, dual-tone resist material, anti-reflective coating (ARC) material, top anti-reflective coating (TARC) material, or bottom anti-reflective coating (BARC) material, or any combination thereof. The protection layer 703 can comprise second masking material that can include second CAR material, second NCAR material, second dual-tone resist material, second ARC material, second TARC material, or second BARC material, or any combination thereof.

The protected features can represent a “desired” final double pattern (DP) structure that is “protected” to preserve the original dimensions when a final DP layer is created. In various examples, the protected features 722 can have thicknesses 722a that can vary from about 5 nm to about 500 nm; the protected features 722 can have widths 722b that can vary from about 5 nm to about 500 nm; the protected features 722 can have periods 722c that can vary from about 15 nm to about 1500 nm; and the protected space regions 723 can have widths 723b that can vary from about 15 nm to about 1500 nm. In addition, the protection layer 703 can have thicknesses 703a that can vary from about 2 nm to about 20 nm; the protection layer 703 can have widths 703b that can vary from about 5 nm to about 50 nm.

FIG. 7C illustrates a protected activated substrate protected having one or more substrate layers 701, one or more target layers 702, and an activated patterned layer 531 on top of the one or more target layers 702. The activated patterned layer 731 can include a plurality of protected activated features 732 separated by a plurality of “non-activated” protected space regions 733. The activated patterned layer 731 can include a protection layer 703 that can be used to protect the plurality of protected activated features 732 and that can be used to establish the plurality of “non-activated” protected space regions 723. Alternatively, the plurality of “non-activated” protected space regions 723 may not be required or may be configured differently.

In some embodiments, a first protected activated substrate 730 can be created by performing a first radiation procedure using one or more of the processing elements in the processing system (1, FIGS. 1-3). For example, a plurality of protected activated features 732 and a plurality of “non-activated” protected space regions 733 can be created at a first number of sites on the first protected activated substrate 730.

The activated patterned layer 731 can include a plurality of protected activated features 732 separated by a plurality of “non-activated” protected space regions 733, and the protected activated features 732 can include a modified first masking material that has been activated (modified) by a first radiation pattern 709a. For example, the first radiation pattern 709a can include a first set of wavelengths, and the protection layer 703 can be substantially transparent to one or more of the first set of wavelengths. In addition, the protected activated features 732 can include activated (modified) CAR material, activated (modified) NCAR material, activated (modified) dual-tone resist material, activated (modified) ARC material, activated (modified) TARC material, or activated (modified) BARC material, or any combination thereof.

In some embodiments, a first radiation pattern 709a can be used to create a plurality of first activation species 735 in the plurality of protected activated features 732. In other embodiments, a first radiation pattern 709a can be used with one or more thermal procedures to create a plurality of first activation species 735 in the plurality of protected activated features 732. In still other embodiments, one or more thermal procedures can be used to create a plurality of first activation species 735 in the plurality of protected activated features 732. In various procedures, the first activation species 735 can include one or more chemically-amplified negative components, or one or more chemically-amplified positive components, or any combination thereof. In other examples, the first activation species 735 can include one or more chemically-amplified acid components, or one or more chemically-amplified base components, or any combination thereof.

In various examples, the protected activated features 732 can have thicknesses 732a that can vary from about 5 nm to about 500 nm; the protected activated features 732 can have widths 732b that can vary from about 5 nm to about 500 nm; the protected activated features 732 can have first periods 732c that can vary from about 15 nm to about 1500 nm; and the “non-activated” protected space regions 733 can have space widths 733b that can vary from about 15 nm to about 1500 nm. In addition, the protection layer 703 can have dimensions that are not affected by the exposure procedure.

FIG. 7D illustrates a double-filled substrate 740 having one or more substrate layers 701, one or more target layers 702, and a filled patterned layer 741 on top of the one or more target layers 702. The filled patterned layer 741 can include a plurality of first “previously-activated” features 742 encased in a protection layer 703, and a protection layer 703, a first fill layer 743, and a second fill layer 744 can be configured between the plurality of first “previously-activated” features 742. In addition, the protection layer 703 can comprise a second masking material, the first fill layer 743 can comprise a third masking material, and the second fill layer 744 can comprise a fourth masking material.

The “previously-activated” features 742 can include a first masking material that has been “previously-activated” (modified) by the first radiation pattern 709a. For example, the “previously-activated” first masking material can include “previously-activated” CAR material, “previously-activated” NCAR material, “previously-activated” dual-tone resist material, “previously-activated” ARC material, “previously-activated” TARC material, or “previously-activated” BARC material, or any combination thereof. The third masking material and the fourth masking material can include additional CAR material, additional NCAR material, additional dual-tone resist material, additional ARC material, additional TARC material, or additional BARC material, or any combination thereof.

In various examples, the “previously-activated” features 742 can have thicknesses 742a that can vary from about 5 nm to about 500 nm; the “previously-activated” features 742 can have widths 742b that can vary from about 5 nm to about 500 nm; the “previously-activated” features 742 can have third periods 742c that can vary from about 15 nm to about 1500 nm; the first fill layers 743 can have a first fill thickness 743a that can vary from about 1 nm to about 20 nm; the first fill layers 743 can have first fill widths 743b that can vary from about 1 nm to about 20 nm; the second fill layer 744 can have a second fill thickness 744a that can vary from about 1 nm to about 20 nm; the second fill layer 744 can have second fill widths 744b that can vary from about 1 nm to about 20 nm.

In some examples, the first masking material and/or the second masking material can include one or more chemically-amplified negative components, or one or more chemically-amplified positive components, or any combination thereof. In addition, the third masking material and/or the fourth masking material can include one or more chemically-amplified acid components, or one or more chemically-amplified base components, or any combination thereof.

In other examples, the third masking material and/or the fourth masking material can include one or more chemically-amplified negative components, or one or more chemically-amplified positive components, or any combination thereof. In addition, the third masking material and/or the fourth masking material can include one or more chemically-amplified acid components, or one or more chemically-amplified base components, or any combination thereof.

FIG. 7E illustrates a first de-protected double-patterned-shadow (D-P-S) substrate 750 having one or more substrate layers 701, one or more target layers 702, and a first de-protected (D-P-S) layer 751 on top of the one or more target layers 702. The first de-protected (D-P-S) layer 751 can include a plurality of “de-activating” protected diffusion features 752 that are covered by a protection layer 703, a plurality of self-aligned features 757, a plurality of sidewall angle (SWA) regions 758, a plurality of de-protection regions 753, and a second fill layer 754. Alternatively, the first de-protected layer 751 may be configured differently. For example, the plurality of “de-activating” protected diffusion features 752 can represent “desired” first double pattern (DP) features; the self-aligned features 757 can represent “desired” second double pattern (DP) features; the SWA regions 758 can be used to establish SWA's that can vary from about 80 degrees to about 100 degrees, and the plurality of de-protection regions 753 can “represent” double pattern (DP) spaces between the first and second double pattern (DP) features. Alternatively, the SWA regions 758 and/or the second fill layer 754 may not be present. In addition, the SWA regions 758 can be created by a non-uniform first de-protection procedure, and a second de-protection procedure can be used to establish the correct sidewall angles.

The self-aligned features 757 can include third masking material that remains “protected” (un-developable), and the two sets of de-protection regions 753 that surround the self-aligned features 757 can include third masking material that has been “de-protected” (developable). For example, the de-protection regions 753 can be created and de-protected by moving the first activation species 755 from the “de-activating” protected diffusion features 752 into the two sets of de-protection regions 753. When the first activation species 755 moves into the third masking material in the de-protection regions 753, a third de-protecting species 756 can be activated in the third masking material and the third de-protecting species 756 can move through the third masking material, thereby de-protecting the third masking material and creating the two sets of de-protection regions 753 that can be developable.

In some embodiments, the “de-activating” protected diffusion features 752 can include first masking material that has been “previously-activated” by a first exposure procedure (first radiation pattern 709a), and the “previously-activated” first masking material can be “de-activated” using a second exposure procedure (a second radiation pattern 709b). In other embodiments, the “de-activating” protected diffusion features 752 can include first masking material that has been “previously-activated” by at least one first exposure procedure and at least one first thermal procedure, and the “previously-activated” first masking material can be “de-activated” using at least one second exposure procedure and at least one second thermal procedure. In still other embodiments, the “de-activating” protected diffusion features 752 can include first masking material that has been “previously-activated” by at least one thermal procedure, and the “previously-activated” first masking material can be “de-activated” using at least one second thermal procedure. Alternatively, other combinations of procedures may be used.

The protected diffusion features 752 can include first masking material that has completely or partially “de-activated” and can include “de-activated” CAR material, “de-activated” NCAR material, “de-activated” dual-tone resist material, “de-activated” ARC material, “de-activated” TARC material, or “de-activated” BARC material, or any combination thereof.

In some (D-P-S) de-protecting procedures, the two sets of de-protection regions 753 can include de-protected material, and the de-protected material can include de-protected CAR material, de-protected NCAR material, de-protected dual-tone resist material, de-protected ARC material, de-protected TARC material, or de-protected BARC material, or any combination thereof. In other (D-P-S) de-protecting procedures, the two sets of de-protection regions 753 can include de-blocked material, and the de-blocked material can include de-blocked CAR material, de-blocked NCAR material, de-blocked dual-tone resist material, de-blocked ARC material, de-blocked TARC material, or de-blocked BARC material, or any combination thereof.

In various examples, the protected diffusion features 752 can have thicknesses 752a that can vary from about 5 nm to about 500 nm; the protected diffusion features 752 can have widths 752b that can vary from about 5 nm to about 500 nm; the protected diffusion features 752 can have periods 752c that can vary from about 15 nm to about 1500 nm; the de-protection regions 753 can have thicknesses 753a that can vary from about 5 nm to about 500 nm; the de-protection regions 753 can have widths 753b that can vary from about 5 nm to about 500 nm; the second fill layer 754 can have a second fill thickness 754a that can vary from about 1 nm to about 20 nm; the second fill layer 754 can have second fill widths 754b that can vary from about 5 nm to about 500 nm; the self-aligned features 757 can have feature thicknesses 757a that can vary from about 5 nm to about 500 nm; the self-aligned features 757 can have feature widths 757b that can vary from about 5 nm to about 500 nm; and the self-aligned features 757 can have periods 757c that can vary from about 15 nm to about 1500 nm.

The SWA regions 758 can have SWA thicknesses 758a that can vary from about 5 nm to about 500 nm, and the SWA regions 758 can have SWA widths 758b that can vary from about −15 nm to about +15 nm. For example, when the self-aligned features 757 have been created correctly the SWA widths 758b can vary from about −2 nm to about +2 nm.

FIG. 7F illustrates a second de-protected double-patterned-shadow (D-P-S) substrate 760 having one or more substrate layers 701, one or more target layers 702, and a second de-protected (D-P-S) layer 761 on top of the one or more target layers 702. The second de-protected (D-P-S) layer 761 can include a plurality of first (D-P-S) features 762 that are covered by a protection layer 703, a plurality of “un-developable” self-aligned second (D-P-S) features 767, a plurality of de-protected SWA regions 768, a plurality of de-protected space regions 763, and a second fill layer 754 having a plurality of fourth activation species 705 therein. For example, the first (D-P-S) features 762 can still “represent” first double pattern (DP) features; the “un-developable” self-aligned second (D-P-S) features 767 can still “represent” second double pattern (DP) features; the de-protected SWA regions 768 can be used to represent SWA regions that are being “de-protected”, and the de-protected space regions 763 can “represent” double pattern (DP) spaces between the first and second double pattern (DP) features. In addition, the first (D-P-S) features 762 may be configured differently; the “un-developable” self-aligned second (D-P-S) features 767 may be configured differently; the de-protected SWA regions 768 may be configured differently, the de-protected space regions 763 may be configured differently, and/or the second fill layer 764 may be configured differently. Alternatively, the de-protected SWA regions 768 and/or the second fill layer 764 may not be present.

The “un-developable” self-aligned second (D-P-S) features 767 can include third masking material that remains “protected” (un-developable). In addition, the two sets of de-protected space regions 763 that surround the self-aligned second (D-P-S) features 767 can include third masking material that has been “de-protected” and therefore has become developable.

For example, the previously-processed third masking material in the plurality of de-protected SWA regions 768 can be de-protected by moving the plurality of fourth activation species 705 from the second fill layer 764 into the two sets of previously-processed third masking material. When the fourth activation species 705 moves into the previously-processed third masking material in the de-protected SWA regions 768, a new de-protecting species 706 can be activated in the previously-processed third masking material and the new de-protecting species 706 can move through the previously-processed third masking material, thereby de-protecting the previously-processed third masking material in the de-protected SWA regions 768.

In some embodiments, the second fill layer 764 can include fourth masking material that includes a plurality of fourth activation species 705 that can be activated by a third exposure procedure (third radiation pattern 709c). In other embodiments, the second fill layer 764 can include fourth masking material that includes a plurality of fourth activation species 705 that can be activated by a third exposure procedure (third radiation pattern 709c) and at least one thermal procedure. In still other embodiments, the second fill layer 764 can include fourth masking material that includes a plurality of fourth activation species 705 that can be activated using at least one thermal procedure. Additionally, the second fill layer 764 can include fourth masking material that includes a plurality of fourth activation species 705 that can be activated and/or enhanced using at least one dispensing process. Alternatively, other combinations of procedures may be used.

In various examples, the first (D-P-S) features 762 can have thicknesses 762a that can vary from about 5 nm to about 500 nm; the first (D-P-S) features 762 can have widths 762b that can vary from about 5 nm to about 500 nm; the first (D-P-S) features 762 can have periods 762c that can vary from about 15 nm to about 1500 nm; the de-protected space regions 763 can have thicknesses 763a that can vary from about 5 nm to about 500 nm; the de-protected space regions 763 can have widths 763b that can vary from about 5 nm to about 500 nm; the second fill layer 764 can have a second fill thickness 764a that can vary from about 1 nm to about 20 nm; the second fill layer 764 can have second fill widths 764b that can vary from about 5 nm to about 500 nm; the self-aligned second (D-P-S) features 767 can have feature thicknesses 767a that can vary from about 5 nm to about 500 nm; the “un-developable” self-aligned second (D-P-S) features 767 can have feature widths 767b that can vary from about 5 nm to about 500 nm; and the “un-developable” self-aligned second (D-P-S) features 767 can have periods 767c that can vary from about 15 nm to about 1500 nm.

The de-protected SWA regions 768 can have SWA thicknesses 768a that can vary from about 5 nm to about 500 nm, and the de-protected SWA regions 768 can have SWA widths 768b that can vary from about −2 nm to about +2 nm. For example, when the self-aligned second (D-P-S) features 767 have been created correctly the SWA widths 768b can vary from about −1 nm to about +1 nm.

FIG. 7G illustrates a first developed Double Patterned (DP) substrate 770 having one or more substrate layers 701, one or more target layers 702, and a first developable Double Pattered (DP) layer 771 on top of the one or more target layers 702. During some developing procedures, the second fill layer (764, FIG. 7F) can be removed. The first developable DP layer 771 can include a plurality of non-developable first DP features 772 that are covered by the protection layer 703, a plurality of developable space regions 773, a plurality of developable SWA regions 778, and a plurality of self-aligned second DP features 777. For example, the developable space regions 773 and the developable SWA regions 778 can be configured on both sides of each of the self-aligned second DP features 777. Alternatively, some portions of the protection layer 703, or the developable space regions 773, or the developable SWA regions 778 may also be removed during the developing procedures.

In various examples, the non-developable first DP features 772 can have first thicknesses 772a that can vary from about 5 nm to about 500 nm; the non-developable first DP features 772 can have first widths 772b that can vary from about 5 nm to about 500 nm; the non-developable first DP features 772 can have first periods 772c that can vary from about 15 nm to about 1500 nm. In addition, the self-aligned second DP features 777 can have second thicknesses 777a that can vary from about 5 nm to about 500 nm; the self-aligned second DP features 777 can have second widths 777b that can vary from about 5 nm to about 500 nm; the self-aligned second DP features 777 can have second DP periods 777c that can vary from about 15 nm to about 1500 nm. In addition, the developable space regions 773 can have thicknesses 773a that can vary from about 5 nm to about 500 nm and can have first space widths 773b that can vary from about 10 nm to about 500 nm.

In addition, the two developable SWA regions 778 can have SWA thicknesses 778a that can vary from about 5 nm to about 500 nm, and the two “developable SWA regions 778 can have SWA widths 778b that can vary from about −2 nm to about +2 nm. For example, when the self-aligned second DP features 777 have been created correctly the SWA widths 768b can vary from about −1 nm to about +1 nm.

FIG. 7H illustrates a final Double Patterned (DP) substrate 780 having one or more substrate layers 701, one or more target layers 702, and a final Double Patterned (DP) layer 781 on top of the one or more target layers 702. The final DP layer 781 can include a plurality of final first DP features 782, a plurality of final second DP features 787, and a plurality of final Double Patterned (DP) spaces 783.

For example, one or more additional developing procedures can be performed to remove the de-protected second masking material in the remaining portions of the protection layer (703, FIG. 7G), and/or the remaining portions of the developable space regions (773, FIG. 7G), and/or the remaining portions of the developable SWA regions (778, FIG. 7G), thereby creating the plurality of final DP spaces 783. The final first DP features 782 can include first masking material that has been processed by the one or more developing procedures. The final second DP features 787 can include third masking material that has been processed by the one or more developing procedures. The plurality of final first DP features 782 can include un-developed first masking material that is not de-protected and is not removed during the additional developing procedures. The plurality of final second DP features 787 can include un-developed third masking material that is not de-protected and is not removed during the additional developing procedures.

In various examples, the final first DP features 782 can have the final first DP thicknesses 782a that can vary from about 5 nm to about 500 nm; the final first DP features 782 can have final first DP widths 782b that can vary from about 5 nm to about 500 nm; the final first DP features 782 can have final first DP periods 782c that can vary from about 15 nm to about 1500 nm. In addition, the final second DP features 787 can have final second DP thicknesses 787a that can vary from about 5 nm to about 500 nm; the final second DP features 787 can have final second DP widths 787b that can vary from about 5 nm to about 500 nm; the final second DP features 787 can have final second DP periods 787c that can vary from about 15 nm to about 1500 nm. In addition, the plurality of final DP spaces 783 can have final widths 783b that can vary from about 10 nm to about 500 nm.

In still other embodiments, the (D-P-S) features can comprise multiple layers having different masking materials.

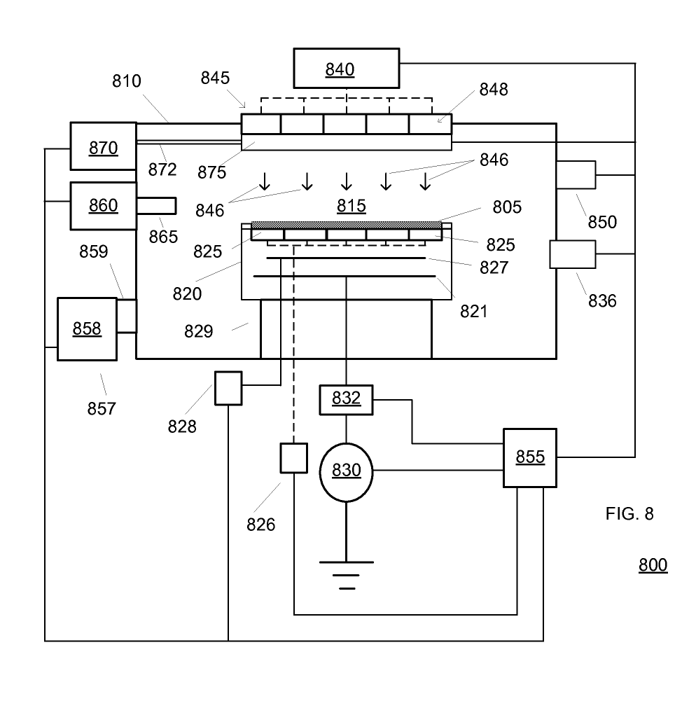

FIG. 8 shows an exemplary block diagram of a Double-Patterned-Shadow (D-P-S) subsystem in accordance with embodiments of the invention. An exemplary (D-P-S) subsystem 800 is shown in FIG. 8, and the illustrated (D-P-S) subsystem 800 can include a processing chamber 810, substrate holder 820, upon which a substrate 805 to be processed can be mounted, and vacuum pumping system 857. For example, substrate holder 820 can be coupled to and insulated from the processing chamber 810 using base 829. Substrate 805 can be, for example, a semiconductor substrate, a work piece, or a liquid crystal display (LCD). In various embodiments, one or more of the (D-P-S) subsystems 800 can be configured within the processing system (1, FIGS. 1-3) and/or coupled to the processing system (1, FIGS. 1-3).

In some embodiments, a fluid supply system 860 can be coupled to the processing chamber 810 and a dispensing system 865 that can be configured to provide one or more process fluids to the surface of substrate 805. Alternatively, process fluids may not be required or may be provided differently. In addition, a gas supply system 870 can be coupled to the processing chamber 810 and to a flow control system 872 that can be configured to provide one or more process gasses to the gas injection system 875. A gas or mixture of gases can be introduced via gas injection system 875 to the process space 815, and the chamber pressure can be adjusted. In some examples, the process gas can be utilized to create processing materials in the processing space 815 that can be specific to a predetermined (D-P-S) procedure in a (D-P-S) processing sequence. In other examples, the process gas can be used when material is being deposited on the substrate 805, such as during a filling procedure or during a protection layer deposition procedure. In still other examples, a different process gas can be used when material is being removed from the substrate 805, such as during a developing procedure or during a substrate cleaning procedure. For example, controller 855 can be used to control vacuum pumping system 857, fluid supply system 860, and gas injection system 870.

Substrate 805 can be, for example, transferred into and out of the processing chamber 810 through a slot valve and chamber feed-through assembly 836 via robotic transfer system (not shown) where it is received by substrate lift pins (not shown) housed within substrate holder 820 and mechanically translated by devices housed therein. After the substrate 805 is received from transfer system, it can be lowered to an upper surface of substrate holder 820. In some examples, substrate 805 can be affixed to the substrate holder 820 via a clamping system (not shown). Furthermore, substrate holder 820 can further include a multi-zone heater assembly 827 that can be coupled to a temperature control system 828. In some examples, one or more temperature control elements 825 can receive backside gas from a backside gas supply system 826 can be used to improve the gas-gap thermal conductance between substrate 805 and substrate holder 820. The multi-zone heater assembly 827 can include resistive heating elements, and/or thermo-electric heaters/coolers.

In some embodiments, the (D-P-S) subsystem 800 can include one or more optical sources 840 that can be coupled to one or more segments 848 in a multi-segmented lens/filter assembly 845. The substrate holder 820 and the multi-segmented lens/filter assembly 845 can be used to establish one or more electric fields across the substrate 805. Each segment 848 in the multi-segmented lens/filter assembly 845 can be independently controlled to provide a uniform or non-uniform radiation pattern 846 during one or more (D-P-S) procedures. In one embodiment, the intensity associated with the radiation pattern 846 can be controlled to cause a solubility change to take place in one or more masking layers on the substrate 805.

In other embodiments, the multi-segmented lens/filter assembly 845 can be configured and operated as a plurality of radiation sources that can be used to direct one or more radiation patterns 847 to the substrate 805. The intensity of the radiation provided by each beam in the radiation pattern can be independently controlled during one or more (D-P-S) procedures. In one embodiment, the intensity can be controlled to cause one or more activation species to be activated in one or more of the layers on the substrate 805, and different activation species can require different intensities.

In some (D-P-S) subsystem configurations, the substrate holder 820 can include a lower electrode 821 that can be coupled to a voltage source 830. A DC voltage can be established on the lower electrode 821 during some (D-P-S) procedures. Alternatively, the voltage source 830 may be a low frequency (AC) source, an RF source, or a microwave source. In other configurations, the lower electrode 821, the voltage source 830, and/or the filter network may not be required. In still other configurations, the signals may be applied to the lower electrode 821 at multiple frequencies.

In some configurations, vacuum pumping system 857 can include a vacuum pump 858 and a gate valve 859 for controlling the chamber pressure. Furthermore, a device for monitoring chamber pressure (not shown) may be coupled to the processing chamber 810. In addition, the pressure in the (D-P-S) chamber can be controlled between approximately 5 mTorr and approximately 400 mTorr during the (D-P-S) procedure.

During some (D-P-S) procedures, an edge temperature and a center temperature can be established for the substrate using the multi-zone heater assembly 827. The edge temperature and a center temperature can vary between approximately 10 degrees Celsius and approximately 70 degrees Celsius during an (D-P-S) procedure. Alternatively, different substrate temperatures may not be required. In addition, the processing time for the (D-P-S) procedure can vary from approximately 30 seconds to approximately 6 minutes.

As depicted in FIG. 8, (D-P-S) subsystem 800 can include one or more sensors 850 coupled to processing chamber 810 to obtain performance data, and controller 855 can be coupled to the sensors 850 to receive performance data. The sensors 850 can include both sensors that are intrinsic to the processing chamber 810 and sensors extrinsic to the processing chamber 810. The sensors 850 can include an Optical Emissions Spectroscopy (OES) sensor that can be used as an End Point Detector (EPD) and can provide EPD data.

Controller 855 can include a microprocessor, memory, and a digital I/O port (potentially including D/A and/or A/D converters) capable of generating control voltages sufficient to communicate and activate inputs to the (D-P-S) subsystem 800 as well as monitor outputs from (D-P-S) subsystem 800. As shown in FIG. 8, controller 855 can be coupled to and exchange information with the substrate holder 820, voltage source 830, multi-segmented upper electrode 845, vacuum pumping system 857, backside gas delivery system 826, temperature control system 828, and sensors 850. A program stored in the memory is utilized to interact with the aforementioned components of the (D-P-S) subsystem 800 according to a stored process recipe.

When a masking layer is created during a (D-P-S) procedure, the masking material can include a non-optically-sensitive polymer that can include a blocking component. In other embodiments, the masking material can include an optically-sensitive polymer that can include a blocking component. In some examples, the masking material can include an acid-sensitive polymer that can be de-protected by an acidic component, and the movement of the acid component can be controlled and/or enhanced using one or more radiation patterns having different intensities and/or different frequencies. In other examples, the masking material can include a base-sensitive polymer that can be de-protected by a base component, and the movement of base component can be controlled and/or enhanced using one or more radiation patterns having different intensities and/or different frequencies. In some other examples, the masking material can include a radiation-sensitive polymer that can be de-protected by exposure to a radiation pattern, and the movement of the de-protecting species can be controlled and/or enhanced using one or more radiation patterns having different intensities and/or different frequencies. In still other examples, the masking material can include a thermally-sensitive polymer that can be de-protected using at least one thermal procedure, and the movement of the de-protecting species can be controlled and/or enhanced using one or more radiation patterns having different intensities and/or different frequencies.

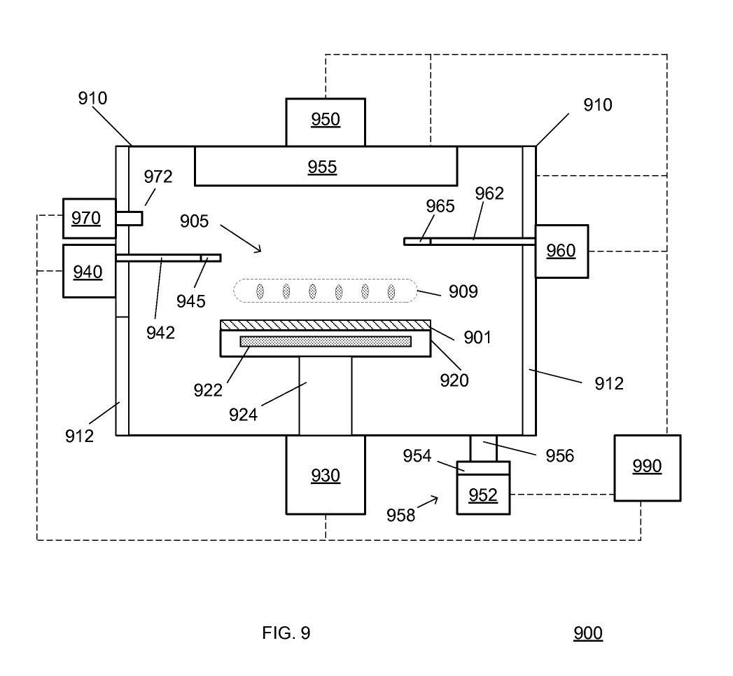

FIG. 9 illustrates a simplified block diagram of an additional Double-Patterned-Shadow (D-P-S) subsystem for processing a (D-P-S) substrate in accordance with embodiments of the invention. The (D-P-S) subsystem 900 comprises a process chamber 910 that includes a substrate holder 920 having temperature control elements 922 that can be configured to elevate and/or lower the temperature of substrate 901. Alternatively, the temperature control elements 922 may include backside gas elements. In addition, the (D-P-S) subsystem 900 can include control elements 930 that can be coupled to a drive mechanism 924 in the process chamber 910, and the control elements 930, the drive mechanism 924, and/or the substrate holder 920 can include biasing elements (not show). The (D-P-S) process chamber 910 can include one or more exhausts port 956 connected to the bottom portion of the process chamber 910 and to a pressure control system 958 that can include a vacuum pump 952 and a gate valve 954. Alternatively, an exhaust port (not shown) may be coupled to the top or side portion of the process chamber 910. The substrate holder 920 can be raised, lowered, and/or rotated by a drive mechanism 924. The substrate can be rotated the substrate in the plane of the substrate surface at a rate of about 1 rpm to about 300 rpm, and the substrate position can be changed by about 20 mm.

The process chamber 910 contains a process space 905 above the substrate 901. The process chamber 910 can include chamber liners 912 made using a ceramic material that can be used to suppress metal contamination of the substrate 901. In addition, one or more of the inner surfaces can be coated with a ceramic material to suppress contamination and facilitate cleaning. Alternatively, chamber liners 912 may not be required.

The (D-P-S) subsystem 900 can include a gas supply system 940 coupled to the process chamber 910. The gas supply system 940 can be coupled to one or more gas-dispensing lines 942 that can be coupled to one or more gas-dispensing nozzle assemblies 945. For example, gas-dispensing nozzle assemblies 945 can provide one or more different gases to the processing space 905 when the dispensing process 909 is being performed. Alternatively, the process gas may be provided across the surface of the substrate 901.

The (D-P-S) subsystem 900 can include a liquid/fluid supply system 960 coupled to the process chamber 910. The liquid/fluid supply system 960 can be coupled to one or more liquid-dispensing lines 962 that can be coupled to one or more liquid-dispensing nozzle assemblies 965. For example, liquid-dispensing nozzle assemblies 965 can provide one or more different liquids and/or fluids to the processing space 905 when the dispensing process 909 is being performed. Alternatively, one or more liquids and/or fluids may be provided across the surface of the substrate 901.

In some embodiments, the process chamber 910 can include one or more supply line 962 coupled to one or more nozzle assemblies 965 that can be positioned above the substrate 901 and can be configured to provide a process fluid and/or a process gas to one or more surfaces of the substrate 901. In other embodiments, the process fluid and/or process gas can be provided to the center portion of the substrate 901, can flow across one or more surfaces of the substrate 901, and can be removed from the process chamber 910 by the exhaust port 956 and the pressure control system 950. Alternatively, the process fluid and/or process gas may be provided from two or more locations above the substrate 901.

In some embodiments, the (D-P-S) subsystem 900 can include a measurement subsystem 970 coupled to the process chamber 910. The process chamber 910 can include one or more sensor ports 972 that can be positioned at one or more locations above the substrate 901 and can be configured to provide process data from the process space 905 above the substrate 901. Alternatively, the measurement subsystem 970 may not be required.

The (D-P-S) subsystem 900 can include an exposure source system 950 coupled to the process chamber 910. The process chamber 910 can include one or more radiation sources 955 coupled to exposure source system 950. The beam systems 955 can be positioned above and/or around the substrate 901 and can be configured to provide a uniform radiation pattern (not shown) to one or more surfaces of the substrate 901. Alternatively, a stepped beam or a scanned beam may be used to improve the uniformity at the edge of the substrate or to eliminate the creation of an edge bead. For example, the beam systems 955 can include amplifiers, filters, combiners, lens, optical fibers, optical wavguides, and the like configured at the proper wavelengths.

In various examples, the exposure source system 950 can include a 254 nm source such as a mercury lamp, a 248 nm source such as a KrF excimer laser, a 222 nm source, such as a KrCl excimer lamp, a 193 nm source such as an ArF excimer laser, a 172 nm source, such as a Xe₂ excimer lamp, a 146 nm source, such as a Kr₂ excimer lamp, a 126 nm source, such as an Ar₂ excimer lamp, a deuterium lamp, an UV source, an UUV, an X-ray source, an EUV source, or an electron beam source, or any combination thereof.

The (D-P-S) subsystem 900 can further comprise a controller 990 that can include a microprocessor, a memory, and a digital I/O port capable of generating control voltages sufficient to communicate and activate inputs of the (D-P-S) subsystem 900 as well as monitor outputs from the (D-P-S) subsystem 900. Moreover, the controller 990 can be coupled to and exchanges information with process chamber 910, the pump 952, the substrate holder 920, gas supply system 940, exposure source system 950, beam systems 955, fluid supply system 960, and the measurement system 970 when they are part of (D-P-S) subsystem 900. The controller 990 may be implemented as an internet-based workstation. In addition, process chamber 910, the pump 952, the substrate holder 920, gas supply system 940, exposure source system 950, beam systems 955, fluid supply system 960, and the remote plasma system 970 can comprise microprocessors and/or digital signal processors (not shown).

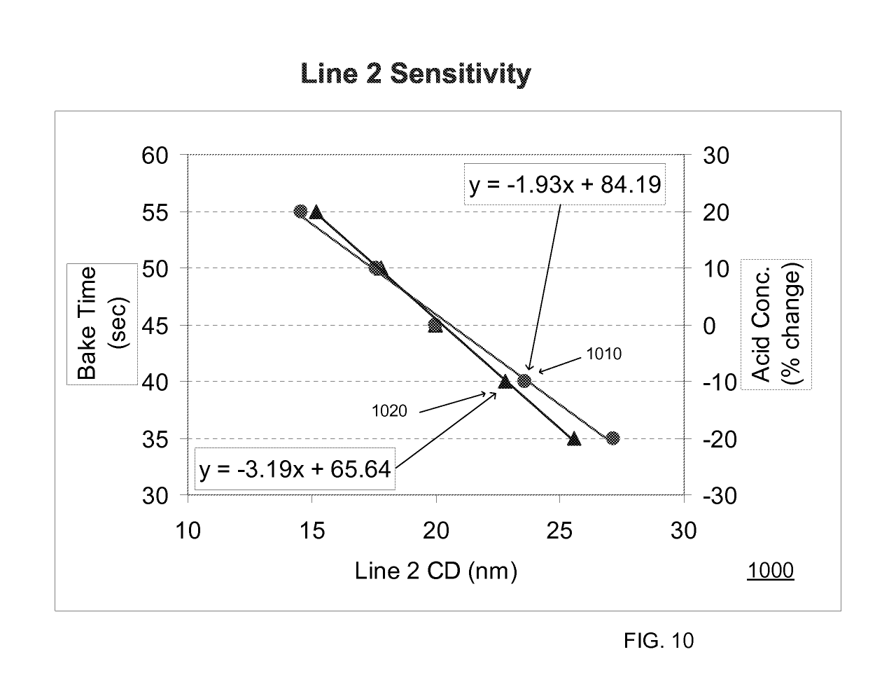

FIG. 10 shows exemplary sensitivity data in accordance with embodiments of the invention. FIG. 10 shows a graph 1000 of exemplary sensitivity data for the critical dimension (CD) data associated with the “self-aligned” feature “line 2”. In the illustrated embodiment, the graph 1000 is shown that includes a first y-axis variable “Bake Time (sec)”, a second y-axis variable “Acid Conc. (% change)”, and an x-axis variable “Line 2 CD (nm)”. In addition, a first set of values 1010 is shown for a first equation (y=−1.93x+84.19), and a second set of values 1020 is shown for a second equation (y=−3.19x+65.64). When (D-P-S) processing sequences are performed, the acid concentration and bake time must be considered. For example, a first line sensitivity graph 1010 is shown in which the line sensitivity is plotted versus the Bake Time, and a second line sensitivity graph 1020 is shown in which the line sensitivity is plotted versus the Acid Concentration (change from nominal activation species concentration. In some embodiments, the final DPS pattern (CD width) can be determined by changing and/or controlling the concentration of activation species, such as shown in FIG. 4A, step 420). In other embodiments, the final DPS pattern (CD width) can be determined by changing and/or controlling the bake time and/or bake temperature. For example, the final CD can be changed by allowing the activated species to migrate a different distance from the protected pattern, thus deprotecting a larger or smaller region between the final DPS patterns. This is the same concept as shown in FIG. 13B, but in that case the inventors have reduced the baseline concentration of base (“quencher”) to allow a farther migration of the activation species. In some examples, the second DPS feature can have a final CD between about 26 nm and about 15 nm by varying the post-exposure bake time. In other examples, the second DPS feature can have a final CD between approximately 28 nm and 15 nm that can be achieved by varying the concentration of activation species during processing.

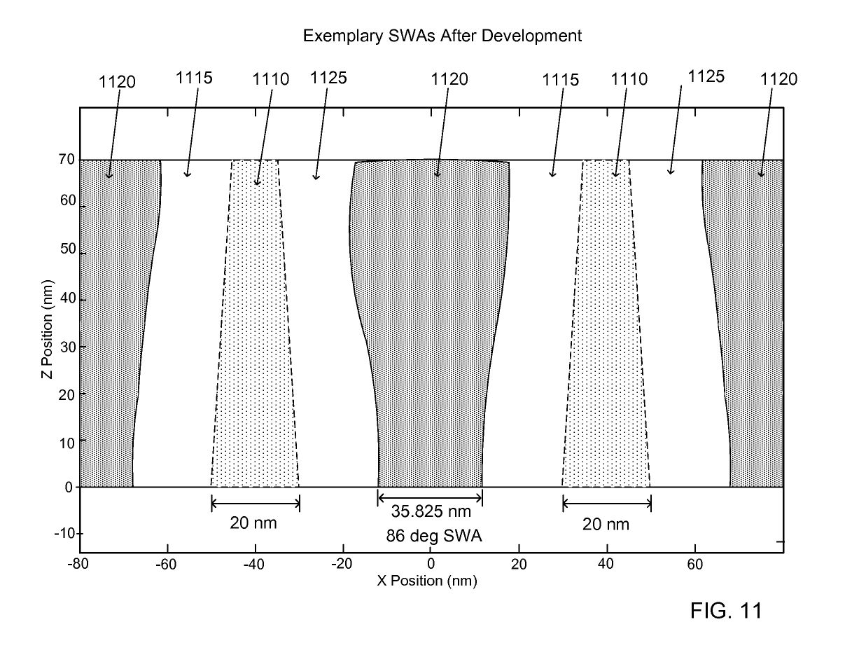

FIG. 11 shows exemplary sidewall angle (SWA) data after development in accordance with embodiments of the invention. In the illustrated embodiment, a plurality of first (reference) features 1110, a plurality of first space regions 1115, a plurality of self-aligned second features 1120, and a plurality of second space regions 1125. In this example, the Double-Patterned-Shadow (D-P-S) procedures that were simulated and/or performed were not correct and each of the first (reference) features 1110 has an incorrect shape (SWA), each of the first space regions 1115 has an incorrect shape (SWA), each of the self-aligned second features 1120 has an incorrect shape (SWA), and each of the second space regions 1125 has an incorrect shape (SWA).

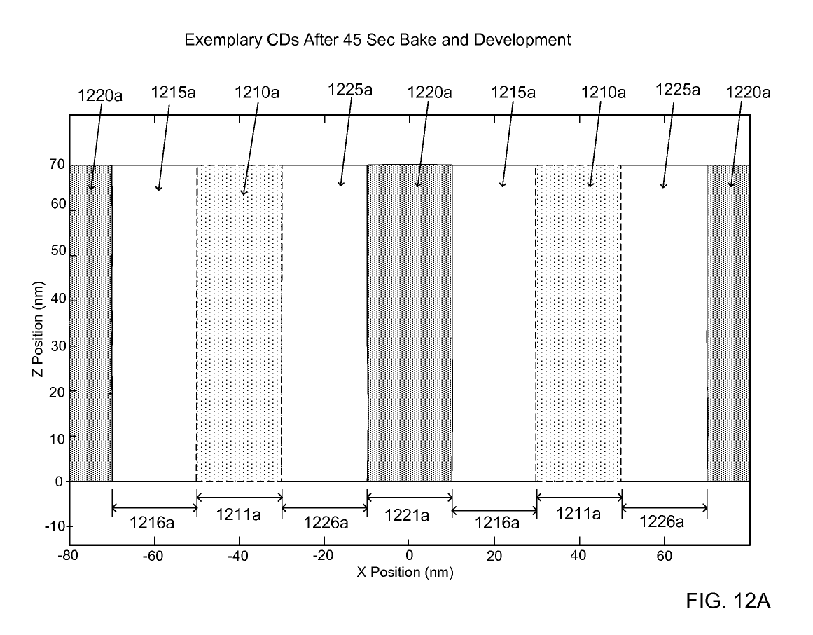

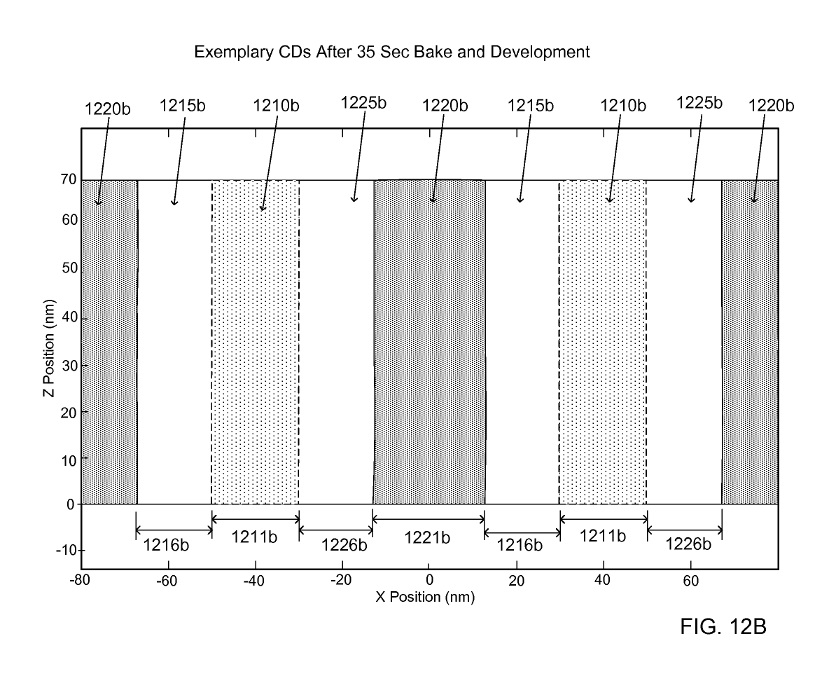

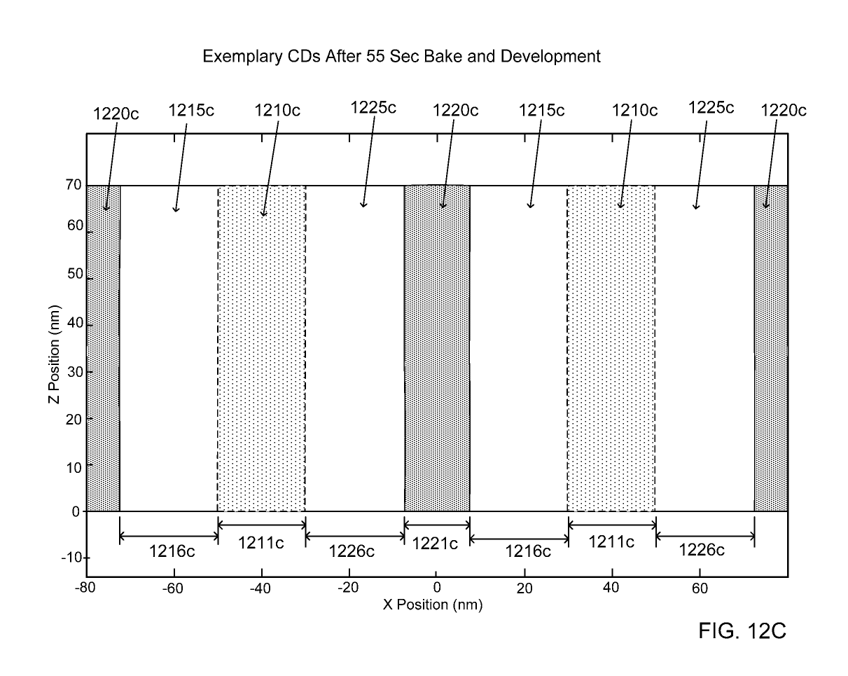

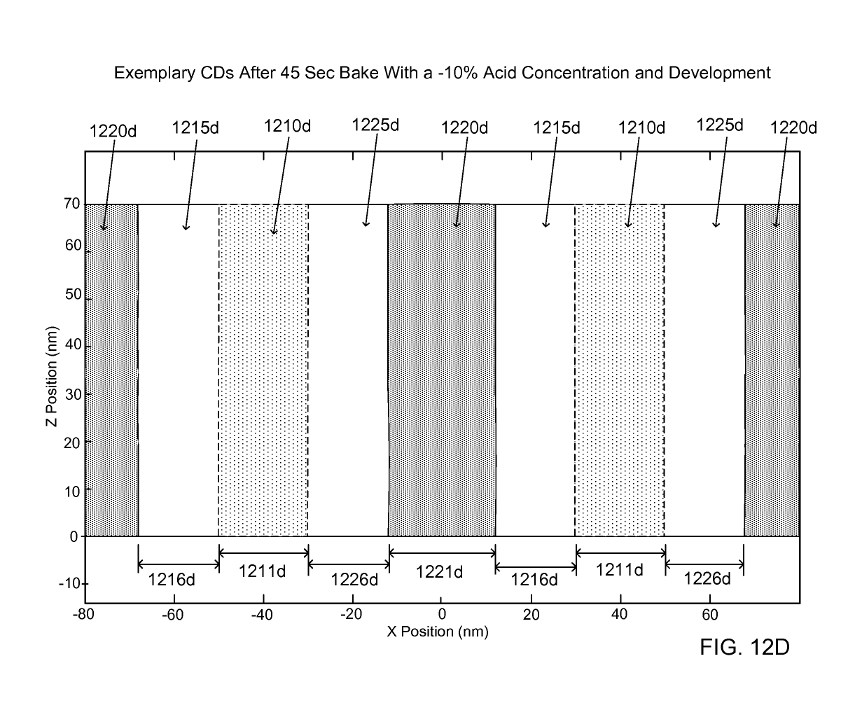

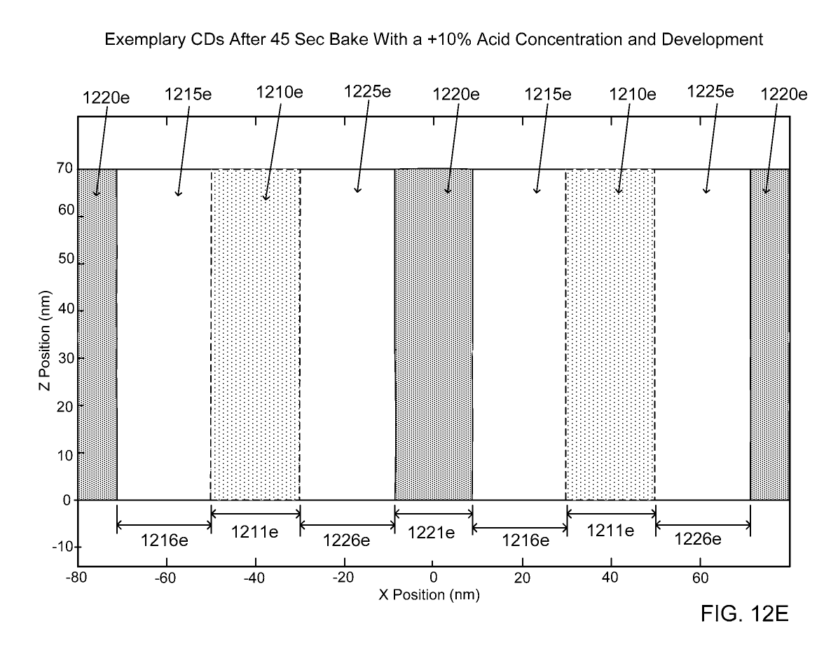

FIGS. 12A-12E show exemplary Double-Patterned-Shadow (D-P-S) data in accordance with embodiments of the invention.

FIG. 12A shows a first set exemplary critical dimension (CD) data after a first correct thermal (bake) procedure and at least one first development procedure have been simulated and/or performed. For example, the first correct thermal (bake) procedure can be performed at 110° C. for 45 seconds. In the illustrated embodiment, a plurality of first (reference) features 1210a, a plurality of first space regions 1215a, a plurality of self-aligned second features 1220a, and a plurality of second space regions 1225a are shown. In this example, the Double-Patterned-Shadow (D-P-S) procedures were simulated and/or performed correctly and each of the first (reference) features 1210a has a correct first feature CD 1211a, a correct first feature shape, and a correct first feature SWA, each of the first space regions 1215a has a correct first space CD 1216a, a correct first space shape, and a correct first space SWA, each of the self-aligned second features 1220a has a correct second feature CD 1221a, a correct second feature shape, and a correct second feature SWA, and each of the second space regions 1225a has a correct second space CD 1226a, a correct second space shape, and a correct second space SWA. When a “20 nm” (D-P-S) procedure is correctly performed, the first feature CD 1211a can vary from about 19.5 nm to about 20.5 nm, the first space CD 1216a can vary from about 19.5 nm to about 20.5 nm, the second feature CD 1221a can vary from about 19.5 nm to about 20.5 nm, and the first space CD 1216a can vary from about 19.5 nm to about 20.5 nm.

FIG. 12B shows a second set exemplary critical dimension (CD) data after a first incorrect thermal (bake) procedure and at least one first development procedure have been simulated and/or performed. For example, the first incorrect thermal (bake) procedure can be performed at 110° C. for 35 seconds. In the illustrated embodiment, a plurality of first (reference) features 1210b, a plurality of first space regions 1215b, a plurality of self-aligned second features 1220b, and a plurality of second space regions 1225b are shown. In this example, the Double-Patterned-Shadow (D-P-S) procedures were simulated and/or performed incorrectly (incorrect bake time) and each of the first (reference) features 1210b can have a correct first feature CD 1211b, a correct first feature shape, and a correct first feature SWA, each of the first space regions 1215b can have a incorrect first space CD 1216b, a incorrect first space shape, and an incorrect first space SWA, each of the self-aligned second features 1220b can have an incorrect second feature CD 1221b, an incorrect second feature shape, and an incorrect second feature SWA, and each of the second space regions 1225b has an incorrect second space CD 1226b, an incorrect second space shape, and an incorrect second space SWA. When a “20 nm” (D-P-S) procedure is incorrectly performed using a shorter than required bake time (35 seconds) the first feature CD 1211b can still vary from about 19.5 nm to about 20.5 nm, the second feature CD 1221b can be larger than the desired value of about 20.0 nm, the first space CD 1216b can be smaller than the desired value of about 20.0 nm, and the first space CD 1216b can be larger than the desired value of about 20.0 nm.

FIG. 12C shows a third set exemplary critical dimension (CD) data after a second incorrect thermal (bake) procedure and at least one first development procedure have been simulated and/or performed. For example, the second incorrect thermal (bake) procedure can be performed at 110° C. for 55 seconds. In the illustrated embodiment, a plurality of first (reference) features 1210c, a plurality of first space regions 1215c, a plurality of self-aligned second features 1220c, and a plurality of second space regions 1225c are shown. In this example, the Double-Patterned-Shadow (D-P-S) procedures were simulated and/or performed incorrectly (incorrect bake time) and each of the first (reference) features 1210c can have a correct first feature CD 1211c, a correct first feature shape, and a correct first feature SWA, each of the first space regions 1215c can have a incorrect first space CD 1216c, a incorrect first space shape, and an incorrect first space SWA, each of the self-aligned second features 1220c can have an incorrect second feature CD 1221c, an incorrect second feature shape, and an incorrect second feature SWA, and each of the second space regions 1225c has an incorrect second space CD 1226c, an incorrect second space shape, and an incorrect second space SWA. When a “20 nm” (D-P-S) procedure is incorrectly performed using a longer than required bake time (55 seconds) the first feature CD 1211c can still vary from about 19.5 nm to about 20.5 nm, the second feature CD 1221c can be smaller than the desired value of about 20.0 nm, the first space CD 1216c can be larger than the desired value of about 20.0 nm, and the first space CD 1216c can be larger than the desired value of about 20.0 nm.

FIG. 12D shows a fourth set exemplary critical dimension (CD) data after a third incorrect thermal (bake) procedure and at least one first development procedure has been simulated and/or performed. For example, the third incorrect thermal (bake) procedure can be performed at 110° C. for 45 seconds with a 10% smaller acid concentration. In the illustrated embodiment, a plurality of first (reference) features 1210d, a plurality of first space regions 1215d, a plurality of self-aligned second features 1220d, and a plurality of second space regions 1225d are shown. In this example, the Double-Patterned-Shadow (D-P-S) procedures were simulated and/or performed incorrectly (incorrect acid concentration) and each of the first (reference) features 1210d can have a correct first feature CD 1211d, a correct first feature shape, and a correct first feature SWA, each of the first space regions 1215d can have a incorrect first space CD 1216d, a incorrect first space shape, and an incorrect first space SWA, each of the self-aligned second features 1220d can have an incorrect second feature CD 1221d, an incorrect second feature shape, and an incorrect second feature SWA, and each of the second space regions 1225d has an incorrect second space CD 1226d, an incorrect second space shape, and an incorrect second space SWA. When a “20 nm” (D-P-S) procedure is incorrectly performed using a smaller acid concentration (−10%) and the previously determined bake time (45 seconds), the first feature CD 1211d can still vary from about 19.5 nm to about 20.5 nm, the second feature CD 1221d can be larger than the desired value of about 20.0 nm, the first space CD 1216d can be smaller than the desired value of about 20.0 nm, and the first space CD 1216d can be smaller than the desired value of about 20.0 nm.

FIG. 12E shows a fifth set exemplary critical dimension (CD) data after a fourth incorrect thermal (bake) procedure and at least one first development procedure have been simulated and/or performed. For example, the third incorrect thermal (bake) procedure can be performed at 110° C. for 45 seconds with a 10% larger acid concentration. In the illustrated embodiment, a plurality of first (reference) features 1210e, a plurality of first space regions 1215e, a plurality of self-aligned second features 1220e, and a plurality of second space regions 1225e are shown. In this example, the Double-Patterned-Shadow (D-P-S) procedures were simulated and/or performed incorrectly (incorrect acid concentration) and each of the first (reference) features 1210e can have a correct first feature CD 1211e, a correct first feature shape, and a correct first feature SWA, each of the first space regions 1215e can have a incorrect first space CD 1216e, a incorrect first space shape, and an incorrect first space SWA, each of the self-aligned second features 1220e can have an incorrect second feature CD 1221e, an incorrect second feature shape, and an incorrect second feature SWA, and each of the second space regions 1225e has an incorrect second space CD 1226e, an incorrect second space shape, and an incorrect second space SWA. When a “20 nm” (D-P-S) procedure is incorrectly performed using a larger acid concentration (+10%) and the previously determined bake time (45 seconds), the first feature CD 1211e can still vary from about 19.5 nm to about 20.5 nm, the second feature CD 1221e can be smaller than the desired value of about 20.0 nm, the first space CD 1216e can be larger than the desired value of about 20.0 nm, and the first space CD 1216e can be larger than the desired value of about 20.0 nm.

FIGS. 13A-13B show exemplary Triple-Patterned-Shadow (T-P-S) data in accordance with embodiments of the invention.

FIG. 13A shows a first set of exemplary critical dimension (CD) data after two sets of Double-Patterned-Shadow (D-P-S) procedures have been simulated and/or performed. In the illustrated embodiment, a plurality of first (reference) features 1310, a plurality of first self-aligned features 1320, a plurality of second self-aligned features 1330, and a plurality of space regions 1335 are shown. In some embodiments, a first set of (D-P-S) procedures can be performed using the first (reference) features 1310 to create a plurality of first self-aligned features 1320. After the first self-aligned features 1320 have been created, a second set of (D-P-S) procedures can be performed using the first (reference) features 1310 and the newly created first self-aligned features 1320 to create the plurality of second self-aligned features 1330.

In one example, one or more first Double-Patterned-Shadow (D-P-S) procedures can be simulated and/or performed using the first (reference) features 1310, which can have been previously established at a 160 nm pitch (period), and during the first (D-P-S) procedures, the first self-aligned features 1320 can be created at a 80 nm pitch (period). Next, one or more second Double-Patterned-Shadow (D-P-S) procedures can be simulated and/or performed using the first (reference) features 1310 and the first self-aligned features 1320, and during the second (D-P-S) procedures, the second self-aligned features 1330 can be created at a 40 nm pitch (period). When the triple patterning sequence is correctly performed, the first (reference) feature 1310 can have a CD 1311 that can vary from about 19.5 nm to about 20.5 nm; the first self-aligned feature 1320 can have a CD 1321 that can vary from about 19.5 nm to about 20.5 nm; the second self-aligned feature 1330 can have a CD 1331 that can vary from about 19.5 nm to about 20.5 nm; and the space regions 1335 can have a CD 1336 that can vary from about 19.5 nm to about 20.5 nm.

FIG. 13B shows a second set of exemplary critical dimension (CD) data in which two sets of Double-Patterned-Shadow (D-P-S) procedures can be simulated and/or performed. In the illustrated embodiment, a graph 1340 is shown that includes a y-axis variable “PAG Multiple” and an x-axis variable “Line 2 CD (nm)”. In addition, a first set of values 1350 is shown for a “100% base example, and a second set of values 1360 is shown for a “10% base example. When triple patterning sequences are performed, the base loading in the first self-aligned features 1320 must be considered in order to compensate for the increased acid consumption across the longer diffusion length.

In some embodiments, the (D-P-S) data can include layer fabrication information and the layer fabrication information can be different for different layers. New (D-P-S) layer data can be obtained during a (D-P-S) procedure and can be used to update and/or optimize process recipes, can be used to update and/or optimize process models, and can be used to update and/or optimize profile data. In addition, the (D-P-S) procedure can send the new (D-P-S) layer data to the controllers in other subsystems and/or the factory system. For example, the new (D-P-S) data can include new substrate thickness data and/or uniformity data. The (D-P-S) procedures can utilize context data such as site ID, chip ID, die ID, product ID, subsystem ID, time, substrate ID, slot ID, lot ID, recipe, and/or patterned structure ID as a means for organizing and indexing substrate data.

In addition, (D-P-S) modeling procedures can create, refine, and/or use a (D-P-S) substrate model, an accuracy model, a recipe model, an optical properties model, a structure model, a FDC model, a prediction model, a confidence model, a measurement model, an etching model, a deposition model, a first substrate effect model, a chamber model, a tool model, a drift model, a delay time model, an electrical performance model, or a device model, or any combination thereof.

In addition, when judgment and/or intervention rules are associated with (D-P-S) procedures, they can be executed. Intervention and/or judgment rule evaluation procedures and/or limits can be performed based on historical procedures, on the customer's experience, or process knowledge, or obtained from a host computer. Rules can be used in FDC procedures to determine how to respond to alarm conditions, error conditions, fault conditions, and/or warning conditions. The FDC procedures can prioritize and/or classify faults, predict system performance, predict preventative maintenance schedules, decrease maintenance downtime, and extend the service life of consumable parts in the system.

The subsystem can take various actions in response to an alarm/fault, depending on the nature of the alarm/fault. The actions taken on the alarm/fault can be context-based, and the context can be specified by a rule, a system/process recipe, a chamber type, identification number, load port number, cassette number, lot number, control job ID, process job ID, slot number and/or the type of data.

One or more (D-P-S) simulation applications can be used to compute predicted data for the substrate based on the input state, the process characteristics, and a process model. (D-P-S) metrology models can be used to predict and/or calculate the smaller structures and/or features associated with the design nodes below 65 nm. For example, prediction models can include process chemistry models, chamber models, EM models, SPC charts, PLS models, PCA models, FDC models, and Multivariate Analysis (MVA) models.

Accuracy values can be determined for (D-P-S) procedures and/or results, the accuracy values can be compared to accuracy limits, and refinement procedures can be performed if the accuracy values do not meet the accuracy limits. Alternatively, other procedures can be performed, other sites can be used, or other substrates can be used.

When a refinement procedure is used, the refinement procedure can utilize bilinear refinement, Lagrange refinement, Cubic Spline refinement, Aitken refinement, weighted average refinement, multi-quadratic refinement, bi-cubic refinement, Turran refinement, wavelet refinement, Bessel's refinement, Everett refinement, finite-difference refinement, Gauss refinement, Hermite refinement, Newton's divided difference refinement, osculating refinement, or Thiele's refinement algorithm, or a combination thereof.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

Thus, the description is not intended to limit the invention and the configuration, operation, and behavior of the present invention has been described with the understanding that modifications and variations of the embodiments are possible, given the level of detail present herein. Accordingly, the preceding detailed description is not meant or intended to, in any way, limit the invention—rather the scope of the invention is defined by the appended claims.

What is claimed is:

1. A method of creating a Double Patterned (DP) substrate comprising:
selecting a first patterned substrate from a first set of patterned substrates received by a processing system, wherein the first patterned substrate comprises a plurality of first features having a first masking material therein and a plurality of space regions between the first features, wherein the first features and the space regions are established on a target layer;
creating a first protected substrate by depositing a protection layer on the first patterned substrate, wherein a plurality of protected first features and a plurality of protected space regions are established on the target layer on the first protected substrate;
creating a protected activated substrate by performing a first exposure procedure using the first protected substrate, wherein a plurality of protected activated features having a first activation species therein and a plurality of protected non-activated space regions are established on the target layer on the protected activated substrate, each of the protected activated features having a first protection layer thereon and each protected non-activated space region having a second protection layer therein;
creating a first filled substrate by performing a first fill procedure using the protected activated substrate, wherein one or more first fill layers are established on the target layer on the first filled substrate, each first fill layer being established between two of the protected activated features on the target layer on the first filled substrate;
creating a first de-protected Double-Patterned-Shadow (D-P-S) substrate by performing a first de-protecting procedure using the first filled substrate, wherein a plurality of protected diffusion features having the first activation species therein, a plurality of de-protection regions, and a plurality of self-aligned second (D-P-S) features are established on the target layer on the first de-protected (D-P-S) substrate, each protected diffusion feature having two de-protection regions adjacent thereto and each self-aligned second (D-P-S) feature being established between two of the de-protection regions, the first activation species in the protected diffusion feature diffusing through the protection layer covering the protected diffusion feature into the first fill layer during the first de-protecting procedure, thereby creating the de-protection regions and the self-aligned second (D-P-S) features therein; and
creating the DP substrate by performing final developing procedures using the first de-protected (D-P-S) substrate.

2. The method of claim 1, wherein the protection layer includes a second masking material that is configured to be selectively permeable to one or more of the first activation species.

3. The method of claim 1, wherein the first exposure procedure includes a first radiation procedure, or a first thermal procedure, or a combination thereof.

4. The method of claim 1, wherein the first exposure procedure includes a first radiation pattern having a first set of wavelengths, and the protection layer includes a second masking material that is configured to be selectively transparent to one or more of the first set of wavelengths.

5. The method of claim 1, wherein the target layer includes semiconductor material, low-k dielectric material, ultra-low-k dielectric material, ceramic material, glass material, metallic material, resist material, filler material, doped material, un-doped material, stressed material, oxygen-containing material, nitrogen-containing material, carbon-containing material, anti-reflective coating (ARC) material, or bottom anti-reflective coating (BARC) material, or any combination thereof.

6. The method of claim 1, wherein the first de-protecting procedure further comprises:
diffusing at least one first activation species from at least one of the protected diffusion features through the protection layer and into a third masking material in a first portion of the first fill layer using a second exposure procedure, or a second thermal procedure, or any combination thereof, thereby creating a plurality of third de-protecting species in the third masking material;
moving the third de-protecting species through the first portion of the third masking material in the first fill layer using the second exposure procedure and/or the second thermal procedure, wherein the first portion of the third masking material is de-protected to create the de-protection regions; and
preventing the third de-protecting species from moving through a second portion of the third masking material in the first fill layer, thereby creating the self-aligned second (D-P-S) features, wherein the third masking material in the self-aligned second (D-P-S) features is not de-protected and is not developable.

7. The method of claim 6, wherein the third masking material comprises chemically amplified resist (CAR) material, non-chemically amplified resist (NCAR) material, dual-tone resist material, anti-reflective coating (ARC) material, top anti-reflective coating (TARC) material, or bottom anti-reflective coating (BARC) material, or any combination thereof.

8. The method of claim 6, wherein the second exposure procedure includes a second set of wavelengths and the protection layer is substantially transparent one or more of the second set of wavelengths.

9. The method of claim 1, wherein the final developing procedures comprises:
establishing a plurality of final first Double Patterned (DP) features by removing the protection layer from the protected diffusion features using a first developing procedure;
establishing a plurality of final Double Patterned (DP) space regions by removing the de-protection regions using a second developing procedure; and
establishing a plurality of final second Double Patterned (DP) features using the self-aligned second (D-P-S) features, wherein each final DP space region is created adjacent to each final first DP feature, and each final second DP feature being created between two final DP space regions.

10. The method of claim 1, wherein the first masking material comprises chemically amplified resist (CAR) material, non-chemically amplified resist (NCAR) material, dual-tone resist material, anti-reflective coating (ARC) material, top anti-reflective coating (TARC) material, or bottom anti-reflective coating (BARC) material, or any combination thereof.

11. A method of creating a Double Patterned (DP) substrate comprising:
selecting a first patterned substrate from a first set of patterned substrates received by a processing system, wherein the first patterned substrate comprises a plurality of first features having a first masking material therein and a plurality of space regions between the first features;
creating a protected substrate by depositing a protection layer on the first patterned substrate, wherein a plurality of protected first features and a plurality of protected space regions are established on a target layer on the protected substrate, each protected space region being created between two of the protected first features;
creating a protected activated substrate by performing a first exposure procedure using the protected substrate, wherein a plurality of protected activated features having a first activation species therein and a plurality of protected non-activated space regions are established on the target layer on the protected activated substrate;
creating a double-filled substrate by performing a first fill procedure and a second fill procedure using the protected activated substrate, wherein the first fill procedure creates a first fill layer between two of the protected activated features and the second fill procedure creates a second fill layer on top of the first fill layer between two of the protected activated features, the second fill layer including a fourth activation species;
creating a first de-protected Double-Patterned-Shadow (D-P-S) substrate by performing a first de-protecting procedure using the double-filled substrate, wherein a plurality of protected diffusion features having the first activation species therein, a plurality of de-protection regions, a plurality of sidewall angle (SWA) regions, a plurality of self-aligned features, and at least one second fill layer are established on the target layer on the first de-protected (D-P-S) substrate, the first activation species in the protected diffusion feature diffusing through the protection layer covering the protected diffusion feature into the first fill layer during the first de-protecting procedure, thereby creating the de-protection regions, the SWA regions, and the self-aligned features therein;
creating a second de-protected Double-Patterned-Shadow (D-P-S) substrate by performing a second de-protecting procedure using the first de-protected (D-P-S) substrate, wherein a plurality of first (D-P-S) features, a plurality of de-protected space regions, a plurality of de-protected sidewall angle (SWA) regions, and a plurality of self-aligned second (D-P-S) features are established on the target layer on the second de-protected (D-P-S) substrate, wherein a third exposure procedure is performed to move the fourth activation species from the second fill layer into a new portion of the first fill layer to create the de-protected SWA regions; and
creating the DP substrate by performing one or more developing procedures using the second de-protected (D-P-S) substrate.

12. The method of claim 11, wherein the protection layer includes a second masking material that is configured to be selectively permeable to one or more of the first activation species.

13. The method of claim 11, wherein the first exposure procedure includes a first radiation procedure, or a first thermal procedure, or a combination thereof.

14. The method of claim 11, wherein the first exposure procedure includes (radiation at?) a first set of wavelengths, and the protection layer includes a second masking material that is configured to be selectively transparent to one or more of the first set of wavelengths.

15. The method of claim 11, wherein the target layer includes semiconductor material, low-k dielectric material, ultra-low-k dielectric material, ceramic material, glass material, metallic material, resist material, filler material, doped material, un-doped material, stressed material, oxygen-containing material, nitrogen-containing material, carbon-containing material, anti-reflective coating (ARC) material, or bottom anti-reflective coating (BARC) material, or any combination thereof.

16. The method of claim 11, wherein the first de-protecting procedure further comprises:
diffusing at least one first activation species from at least one of the protected diffusion features through the protection layer and into the third masking material in a first portion of the first fill layer using a second exposure procedure, or a second thermal procedure, or any combination thereof, thereby creating a plurality of third de-protecting species in the third masking material;
moving the third de-protecting species through the first portion of the third masking material in the first fill layer using the second exposure procedure and/or the second thermal procedure, wherein the first portion of the third masking material is de-protected to create the de-protection regions; and
preventing the third de-protecting species from moving through a second portion of the third masking material in the first fill layer, thereby creating the self-aligned features and the SWA regions, wherein the third masking material in the self-aligned features and the SWA regions is not de-protected and is not developable.

17. The method of claim 16, wherein the third masking material comprises chemically amplified resist (CAR) material, non-chemically amplified resist (NCAR) material, dual-tone resist material, anti-reflective coating (ARC) material, top anti-reflective coating (TARC) material, or bottom anti-reflective coating (BARC) material, or any combination thereof.

18. The method of claim 16, wherein the second exposure procedure includes a second radiation pattern having a second set of wavelengths and the protection layer is substantially transparent one or more of the second set of wavelengths.

19. The method of claim 11, wherein the second de-protecting procedure comprises:
activating the fourth activation species using the third exposure procedure, a third thermal procedure, or a dispensing process, or any combination thereof;
diffusing the fourth activation species from the second fill layer into new portions of the third masking material in the first fill layer using the third exposure procedure, the third thermal procedure, or the dispensing process, or any combination thereof, thereby creating a plurality of new de-protecting species in the new portions of the third masking material in the first fill layer;
moving the new de-protecting species through the new portions of the third masking material in the first fill layer using the third exposure procedure, the third thermal procedure, or the dispensing process, or any combination thereof, wherein the new portions of the third masking material are de-protected and the de-protected SWA regions having de-protected material therein are created; and
preventing the new de-protecting species from moving through the third masking material in the self-aligned second (D-P-S) features, wherein the third masking material in the self-aligned second (D-P-S) features is not de-protected and is not developable.

20. The method of claim 19, wherein performing the one or more developing procedures comprises:
establishing a plurality of final first Double Patterned (DP) features by removing the protection layer from the protected diffusion features using a first developing procedure;
establishing a plurality of final Double Patterned (DP) space regions by removing the de-protection regions using a second developing procedure; and
establishing a plurality of final second Double Patterned (DP) features using the self-aligned second (D-P-S) features, wherein each final DP space region is created adjacent to each final first DP feature, and each final second DP feature being created between two final DP space regions.
